(19) United States
(12) Patent Application Publication
(10) Pub. No.: US 2026/0212895 A1
(43) Pub. Date: Jul. 23, 2026

(54) SEMICONDUCTOR DEVICE, OPERATING METHOD OF SEMICONDUCTOR DEVICE, AND MEMORY SYSTEM

(71) Applicant: YANGTZE MEMORY TECHNOLOGIES HOLDING CO., LTD., Wuhan (CN)

(72) Inventors: Yu ZHANG, Wuhan (CN); ZongLiang HUO, Wuhan (CN); Lei JIN, Wuhan (CN); Feng XU, Wuhan (CN); Da LI, Wuhan (CN)

(21) Appl. No.: 19/441,642

(22) Filed: Jan. 6, 2026

(30) Foreign Application Priority Data
Jan. 23, 2025 (CN) 2025101118831

(51) Int. Cl. G11C 5/02; G11C 5/06; G11C 16/04; G11C 16/16; G11C 16/34

(52) U.S. Cl. CPC G11C 5/025; G11C 5/063; G11C 16/0483; G11C 16/16; G11C 16/3431

(57) ABSTRACT

The present disclosure provides a semiconductor device including a memory cell array and a peripheral circuit coupled to the memory cell array. The memory cell array includes memory banks, and each of the memory banks includes at least one memory block in a first type of program state; the peripheral circuit writes data of at least one first memory block into at least one second memory block to obtain the second memory block in a second type of program state. The first memory block and the second memory block are different memory blocks in memory blocks of a target memory bank, and the first memory block includes a memory block in the first type of program state; and erase data of the first memory block, until each memory block in the first type of program state in the target memory bank is erased once.

### CROSS-REFERENCE TO RELATED APPLICATIONS

The present disclosure claims priority to Chinese Patent Application No. 2025101118831, which was filed Jan. 23, 2025, and is hereby incorporated herein by reference in its entirety.

### FIELD OF TECHNOLOGY

The present disclosure relates to the field of semiconductor technologies, and in particular, to a semiconductor device, an operating method of the semiconductor device, and a memory system.

### BACKGROUND

A semiconductor device, such as a NAND semiconductor device, comprises a plurality of memory blocks, and in a process of using the semiconductor device, because the usage frequencies of different memory blocks differ greatly, memory blocks that are used more frequently are prone to damage, thereby affecting performance of the entire semiconductor device.

### SUMMARY

The examples of the present disclosure provide a semiconductor device, an operating method of the semiconductor device and a memory system.

According to a first aspect, an example of the present disclosure provides a semiconductor device, comprising: a memory cell array and a peripheral circuit coupled to the memory cell array. The memory cell array comprises a plurality of memory planes. Each of the memory planes comprises a plurality of memory banks, and each of the memory banks comprises at least one memory block in a first type of program state. The peripheral circuit writes data of at least one first memory block into at least one second memory block to obtain the second memory block in a second type of program state. The first memory block and the second memory block are different memory blocks in a plurality of memory blocks of a target memory bank, and the first memory block comprises a memory block in the first type of program state. The peripheral circuit erases data of the first memory block, until each memory block in the first type of program state in the target memory bank is erased once.

In some possible implementations, a memory block in the first type of program state comprises a memory block in a program state in the target memory bank between two adjacent data migration cycles. A memory block in the second type of program state comprises a memory block on which a program operation is performed within one data migration cycle. One data migration cycle comprises a duration in which each memory block in the first type of program state in the target memory bank is erased once.

In some possible implementations, a number of the at least one first memory block is greater than a number of the at least one second memory block. Or, the number of the at least one first memory block is equal to the number of the at least one second memory block.

In some possible implementations, each of the memory banks comprises a first type of memory block and a second type of memory block. The first type of memory block is in a program state, and a number of at least one memory block in the program state in the target memory bank is equal to a first number. A memory block in the program state comprises a memory block in the first type of program state or a memory block in the second type of program state. The second type of memory block is in an erase state, or is in an erase state after an erase operation is performed. A number of at least one memory block in the erase state in the target memory bank is equal to a second number.

In some possible implementations, the second type of memory block is further configured to replace a failed memory block in at least one first type of memory block.

In some possible implementations, the peripheral circuit is further configured to: write data stored in a first memory bank into a second memory bank. The first memory bank comprises any one of the plurality of memory banks, and a number of at least one failed memory block in the first memory bank is greater than or equal to a first threshold. The second memory bank comprises any one of the plurality of memory banks and a number of at least one failed memory block in the second memory bank is less than a second threshold.

In some possible implementations, each of the memory banks comprises a first type of memory blocks and a second type of memory block, a number of at least one first type of memory block is equal to a first number, and a number of at least one second type of memory block is equal to a second number. The first type of memory blocks is in a program state, and the second type of memory block is configured to replace a failed memory block in at least one first type of memory block. The first threshold is greater than or equal to the second number, and the second threshold is less than the second number.

In some possible implementations, the peripheral circuit is further configured to: write data stored in a first memory bank into a second memory bank. The first memory bank comprises any one of the plurality of memory banks and an erase count of the first memory bank is greater than a third threshold. The second memory bank comprises any one of the plurality of memory banks and an erase count of the second memory bank is less than a fourth threshold. An erase count of a memory bank comprises a mean value of erase counts of the memory blocks in the memory bank, or the erase count of the memory bank comprises a mean value of at least one erase count of at least one memory block in an erase state in the memory bank.

In some possible implementations, the peripheral circuit is further configured to: write data stored in a first memory bank into a third memory bank when a difference between an erase count of the first memory bank and an erase count of the second memory bank is greater than a fifth threshold. An erase count of a memory bank comprises a mean value of erase counts of the memory blocks in the memory bank, or the erase count of the memory bank comprises a mean value of at least one erase count of at least one memory block in an erase state in the memory bank. The first memory bank comprises any one of the plurality of memory banks and the erase count of the first memory bank is maximum, the second memory bank comprises any one of the plurality of memory banks and the erase count of the second memory bank is minimum, and the third memory bank comprises any one of the plurality of memory banks and is different from the first memory bank.

In some possible implementations, between different data migration cycles, an order in which data is written to memory blocks and an order in which data erase is performed on memory blocks are positively correlated, and one data migration cycle comprises a duration in which each memory block in the first type of program state in the target memory bank is erased once.

In some possible implementations, each of the memory banks comprises a first type of memory block and a second type of memory block. The first type of memory block is configured to perform a corresponding operation, and the second type of memory block is configured to replace a failed memory block in at least one first type of memory block. The peripheral circuit is further configured to: control the first type of memory block in the target memory bank to perform a corresponding operation according to first address information. The first address information is mapped to the second type of memory block in the target memory bank.

In some possible implementations, the corresponding operation comprises at least one of: a data write operation, a data read operation, a data erase operation, or a compute-in-memory operation.

In some possible implementations, the first type of memory block is configured to perform a compute-in-memory operation, and the peripheral circuit is configured to: receive a first operation instruction, wherein the first operation instruction comprises the first address information and input data, and the first address information is mapped to the second type of memory block in the target memory bank; and obtain output data according to the first address information and the input data in response to the first operation instruction. The output data comprises an operation result of the input data and data in the first type of memory block in the target memory bank.

In some possible implementations, a memory block in the target memory bank comprises a select line, a word line, and a memory string. The memory string comprises a plurality of transistors, a drain line and a source line of the transistor are alternately coupled, a gate of the transistor is coupled to the word line, and the select line is coupled to a gate line of the transistor at one end of the memory string. The first operation instruction further comprises address information of a selected word line in the target memory block. The peripheral circuit is configured to: in response to the first operation instruction, input the input data to the select line in the target memory block, apply a read voltage to the selected word line, and apply a turn-on voltage to an unselected word line according to the first address information, the address information of the selected word line and the input data, to obtain output data. The output data comprises a current output from the drain line or the source line. The turn-on voltage is greater than the read voltage.

In some possible implementations, the peripheral circuit is configured to: control the first type of memory block in the target memory bank to perform a corresponding operation according to the first address information and second address information. The second address information is mapped to a start memory block in the first type of memory block in the target memory bank.

In some possible implementations, the first type of memory block is configured to perform a compute-in-memory operation. The peripheral circuit is configured to: receive a second operation instruction, wherein the second operation instruction comprises the first address information, the second address information, and input data; and obtain output data according to the first address information, the second address information, and the input data in response to the second operation instruction. The output data comprises an operation result of the input data and data in the first type of memory block in the target memory bank.

In some possible implementations, a memory block in the target memory bank comprises a select line, a word line, and a memory string. The memory string comprises a plurality of transistors, a drain line and a source line of the transistor are alternately coupled, a gate of the transistor is coupled to the word line, and the select line is coupled to a gate line of the transistor at one end of the memory string. The second operation instruction further comprises address information of a selected word line in the target memory block. The peripheral circuit is configured to: in response to the second operation instruction, input the input data to the select line in the target memory block, apply a read voltage to the selected word line, and apply a turn-on voltage to an unselected word line according to the first address information, the second address information, the address information of the selected word line, and the input data, to obtain output data. The output data comprises a current output from the drain line or the source line. The turn-on voltage is greater than the read voltage.

According to a second aspect, an example of the present disclosure provides an operating method of a semiconductor device, comprising: writing data of at least one first memory block into at least one second memory block to obtain the second memory block in a second type of program state, wherein the first memory block and the second memory block are different memory blocks in a plurality of memory blocks of a target memory bank, and the first memory block comprises a memory block in a first type of program state; and erasing data of the first memory block, until each memory block in the first type of program state in the target memory bank is erased once.

In some possible implementations, the operating method further comprises: writing data stored in a first memory bank into a second memory bank. The first memory bank comprises any one of the plurality of memory banks, and a number of at least one failed memory block in the first memory bank is greater than or equal to a first threshold. The second memory bank comprises any one of the plurality of memory banks and a number of at least one failed memory block in the second memory bank is less than a second threshold.

In some possible implementations, the operating method further comprises: writing data stored in a first memory bank into a second memory bank. The first memory bank comprises any one of the plurality of memory banks and an erase count of the first memory bank is greater than a third threshold. The second memory bank comprises any one of the plurality of memory banks and an erase count of the second memory bank is less than a fourth threshold. An erase count of a memory bank comprises a mean value of erase counts of the memory blocks in the memory bank, or the erase count of the memory bank comprises a mean value of at least one erase count of at least one memory block in an erase state in the memory bank.

In some possible implementations, the operating method further comprises: writing data stored in a first memory bank into a third memory bank when a difference between an erase count of the first memory bank and an erase count of the second memory bank is greater than a fifth threshold. An erase count of a memory bank comprises a mean value of erase counts of the memory blocks in the memory bank, or the erase count of the memory bank comprises a mean value of at least one erase count of at least one memory block in an erase state in the memory bank. The first memory bank comprises any one of the plurality of memory banks and the erase count of the first memory bank is maximum, the second memory bank comprises any one of the plurality of memory banks and the erase count of the second memory bank is minimum, and the third memory bank comprises any one of the plurality of memory banks and is different from the first memory bank.

In some possible implementations, the operating method further comprises: controlling the first type of memory block in the target memory bank to perform a corresponding operation according to first address information. The first address information is mapped to the second type of memory block in the target memory bank.

In some possible implementations, controlling the first type of memory block in the target memory bank to perform the corresponding operation according to the first address information comprises: receiving a first operation instruction, wherein the first operation instruction comprises the first address information and input data, and the first address information is mapped to the second type of memory block in the target memory bank; and obtaining output data according to the first address information and the input data in response to the first operation instruction. The output data comprises an operation result of the input data and data in the first type of memory block in the target memory bank.

In some possible implementations, obtaining the output data according to the first address information and the input data in response to the first operation instruction comprises: in response to the first operation instruction, inputting the input data to a select line in the target memory block, applying a read voltage to a selected word line, and applying a turn-on voltage to an unselected word line according to the first address information, address information of the selected word line and the input data, to obtain the output data. The output data comprises a current output from a drain line or a source line. The turn-on voltage is greater than the read voltage.

In some possible implementations, controlling the first type of memory block in the target memory bank to perform the corresponding operation according to the first address information comprises: controlling the first type of memory block in the target memory bank to perform the corresponding operation according to the first address information and second address information. The second address information is mapped to a start memory block in the first type of memory block in the target memory bank.

In some possible implementations, controlling the first type of memory block in the target memory bank to perform the corresponding operation according to the first address information and the second address information comprises: receiving a second operation instruction, wherein the second operation instruction comprises the first address information, the second address information, and input data; and obtaining output data according to the first address information, the second address information, and the input data in response to the second operation instruction. The output data comprises an operation result of the input data and data in the first type of memory block in the target memory bank.

In some possible implementations, obtaining the output data according to the first address information, the second address information, and the input data in response to the second operation instruction comprises: in response to the second operation instruction, inputting the input data to a select line in the target memory block, applying a read voltage to a selected word line, and applying a turn-on voltage to an unselected word line according to the first address information, the second address information, address information of the selected word line, and the input data, to obtain the output data. The output data comprises a current output from a drain line or a source line. The turn-on voltage is greater than the read voltage.

According to a third aspect, an example of the present disclosure provides a memory system, comprising a processing circuit and any semiconductor device according to the first aspect, wherein the processing circuit is coupled to the semiconductor device.

In some possible implementations, the processing circuit is configured to: send a third operation instruction, wherein the third operation instruction comprises third address information and fourth address information, the third address information is mapped to the at least one first memory block, the fourth address information is mapped to the at least one second memory block, and the first memory block comprises a memory block in the first type of program state; The semiconductor device is configured to: write the data of the at least one first memory block into the at least one second memory block to obtain the second memory block in the second type of program state, wherein the first memory block and the second memory block are different memory blocks in the plurality of memory blocks of the target memory bank; and erase data of the first memory block, until each memory block in the first type of program state in the target memory bank is erased once.

In some possible implementations, the processing circuit is configured to: obtain management information of memory blocks in each of the plurality of memory banks, wherein a memory block in the memory bank comprises a plurality of pages, and one page comprised in the plurality of pages is stored with the management information; and the management information is configured to indicate whether a memory block is a failed memory block. The processing circuit is configured to: write the data stored in the first memory bank into the second memory bank. The first memory bank comprises any one of the plurality of memory banks, and a number of at least one failed memory block in the first memory bank is greater than or equal to a first threshold. The second memory bank comprises any one of the plurality of memory banks and a number of at least one failed memory block in the second memory bank is less than a second threshold.

In some possible implementations, when the management information is 0xFF, it is indicated that a current memory block is a failed memory block.

According to a fourth aspect, an example of the present disclosure provides an electronic device, comprising a host and any memory system according to the third aspect, wherein the host is coupled to the memory system.

According to a fifth aspect, an example of the present disclosure provides an electronic device, comprising a host and any semiconductor device according to the first aspect, wherein the host is coupled to the semiconductor device.

According to a sixth aspect, an example of the present disclosure provides a computer memory medium comprising an instruction. The instruction, when running on a processor, causes the processor to perform the operating method of any semiconductor device according to the second aspect.

### BRIEF DESCRIPTION OF THE DRAWINGS

In order to more clearly illustrate the technical solutions in the present disclosure, the drawings, which need to be used in some examples of the present disclosure, are briefly introduced below, and it is apparent that the drawings in the following description are merely drawings of some examples of the present disclosure, and other drawings may be obtained by those skilled in the art based on these drawings. In addition, the drawings in the following description may be regarded as schematic diagrams, and do not limit the actual size of the product, the actual flow of the method, the actual timing of the signal, and the like involved in the present disclosure.

FIG. 1 is a first schematic structural diagram of an electronic device according to some examples;

FIG. 2 is a second schematic structural diagram of an electronic device according to some examples;

FIG. 3 is a first schematic structural diagram of a semiconductor device according to some examples;

FIG. 4 is a third schematic structural diagram of an electronic device according to some examples;

FIG. 5 is a schematic structural diagram of a memory card according to some examples;

FIG. 6 is a schematic structural diagram of a solid-state drive according to some examples;

FIG. 7 is a second schematic structural diagram of a semiconductor device according to some examples;

FIG. 8 is a third schematic structural diagram of a semiconductor device according to some examples;

FIG. 9 is a fourth schematic structural diagram of a semiconductor device according to some examples;

FIG. 10 is a schematic structural cross-sectional view of a memory string in a semiconductor device according to some examples;

FIG. 11 is a fifth schematic structural diagram of a semiconductor device according to some examples;

FIG. 12 is a fourth schematic structural diagram of an electronic device according to some examples;

FIG. 13 is a first schematic diagram of a bad block management method according to some examples;

FIG. 14 is a second schematic diagram of a bad block management method according to some examples;

FIG. 15 is a third schematic diagram of a bad block management method according to some examples;

FIG. 16 is a sixth schematic structural diagram of a semiconductor device according to some examples;

FIG. 17 is a seventh schematic structural diagram of a semiconductor device according to some examples;

FIG. 18 is a schematic diagram of threshold voltage distribution according to some examples;

FIG. 19 is a fourth schematic diagram of a bad block management method according to some examples;

FIG. 20 is a fifth schematic diagram of a bad block management method according to some examples;

FIG. 21 is an eighth schematic structural diagram of a semiconductor device according to some examples;

FIG. 22 is a first schematic flowchart of an operating method according to some examples;

FIG. 23 is a first schematic structural diagram of a compute-in-memory device according to some examples;

FIG. 24 is a second schematic structural diagram of a compute-in-memory device according to some examples;

FIG. 25 is a third schematic structural diagram of a compute-in-memory device according to some examples;

FIG. 26 is a ninth schematic structural diagram of a semiconductor device according to some examples;

FIG. 27 is a second schematic flowchart of an operating method according to some examples;

FIG. 28 is a third schematic flowchart of an operating method according to some examples;

FIG. 29 is a first schematic structural diagram of a memory bank according to some examples;

FIG. 30 is a second schematic structural diagram of a memory bank according to some examples;

FIG. 31 is a first schematic flowchart of a data migration operation according to some examples;

FIG. 32 is a second schematic flowchart of a data migration operation according to some examples;

FIG. 33 is a third schematic flowchart of a data migration operation according to some examples;

FIG. 34 is a fourth schematic flowchart of a data migration operation according to some examples;

FIG. 35 is a fifth schematic flowchart of a data migration operation according to some examples;

FIG. 36 is a sixth schematic flowchart of a data migration operation according to some examples;

FIG. 37 is a seventh schematic flowchart of a data migration operation according to some examples;

FIG. 38 is an eighth schematic flowchart of a data migration operation according to some examples;

FIG. 39 is a fourth schematic flowchart of an operating method according to some examples;

FIG. 40 is a fifth schematic flowchart of an operating method according to some examples;

FIG. 41 is a sixth schematic flowchart of an operating method according to some examples;

FIG. 42 is a seventh schematic flowchart of an operating method according to some examples;

FIG. 43 is an eighth schematic flowchart of an operating method according to some examples;

FIG. 44 is a ninth schematic flowchart of an operating method according to some examples;

FIG. 45 is a tenth schematic flowchart of an operating method according to some examples.

### DETAILED DESCRIPTION

The technical solutions in some examples of the present disclosure will be clearly and fully described below with reference to the drawings, and it is apparent that the described examples are only a part of examples of the present disclosure, and are not all examples. All other examples obtained by those skilled in the art based on the examples provided by the present disclosure fall within the scope of the present disclosure.

Unless otherwise required by the context, throughout the specification and claims, the term “comprises” is interpreted as open and inclusive, meaning “comprising, but not limited to”. In the description of the specification, the terms “one example,” “some examples,” “exemplary example,” “exemplary,” and the like are intended to indicate that the example or a particular feature, structure, material, or characteristic associated with the example is comprised in at least one example of the present disclosure. The schematic representation of the above terms does not necessarily refer to the same example. Further, the particular feature, structure, material, or characteristic described may be comprised in any suitable manner in any one or more examples.

The terms “first” and “second” are used for descriptive purposes only and are not to be construed as indicating or implying relative importance or implicitly indicating the number of indicated technical features. Thus, features defined by “first”, “second” may explicitly or implicitly comprise one or more of the features. In the description of the examples of the present disclosure, unless otherwise indicated, the meaning of “a plurality of” is two or more.

In describing some examples, “coupled with,” “coupled to,” and “connected to,” and their derivatives, may be used. For example, the term “connected to” may be used in describing some examples to indicate that two or more components are in direct physical contact or electrical contact with each other. As another example, the term “coupled to” may be used in describing some examples to indicate that two or more components in direct physical contact or electrical contact with each other. However, the term “coupled to” may also mean that two or more components are not in direct contact with each other but still cooperate or interact with each other. The examples disclosed herein are not necessarily limited to the disclosure herein.

“At least one of A, B, and C” has the same meaning as “at least one of A, B, or C”, both comprising the following combinations of A, B, and C: A only, B only, C only, a combination of A and B, a combination of A and C, a combination of B and C, and a combination of A, B, and C.

“A and/or B” comprises the following three combinations: A only, B only, and a combination of A and B.

The use of “adapted to” or “configured to” herein means an open and inclusive language that does not exclude devices adapted to or configured to perform additional tasks or operations.

In addition, the use of “based on” means open and inclusive, since in practice, the process, operation, calculation, or other action “based on” one or more of the conditions or values may be based on additional conditions or beyond the values.

The present disclosure is not limited to three-dimensional (3D) NAND semiconductor devices, although 3D NAND semiconductor devices may be used in some examples to illustrate. For example, the techniques disclosed herein may be applied to planar NAND semiconductor devices and NOR semiconductor devices, and the like.

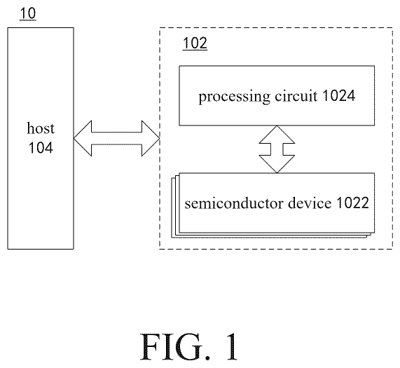

FIG. 1 illustrates a structural diagram of an electronic device 10 having a semiconductor device according to some aspects. The electronic device 10 may be a mobile phone (for example, a cellphone), a desktop computer, a tablet computer, a notebook computer, a server, a vehicle-mounted device, a game console, a printer, a positioning device, a wearable device (for example, a smart watch, a smart bracelet, smart glasses, etc.), a smart sensor, a mobile power source, a virtual reality (VR) device, an augmented reality (AR) device, or any other suitable electronic device having a memory therein.

As shown in FIG. 1, the electronic device 10 comprises a memory system 102 and a host 104. The memory system 102 comprises one or more semiconductor devices 1022 and a processing circuit 1024, the processing circuit 1024 coupled to the semiconductor device 1022. The processing circuit 1024 may be a controller.

The host 104 may be a processor of the electronic device 10, for example, the processor may be a chip, in particular, may be a field programmable gate array (FPGA), may be an application specific integrated circuit (ASIC), or may be a system on chip (SoC), or may be a central processor unit (CPU), or may be a network processor (NP), or may be a digital signal processor (DSP), or may be a microcontroller unit (MCU), or may be a programmable logic device (PLD), or may be an application processor (AP) or another integrated chip.

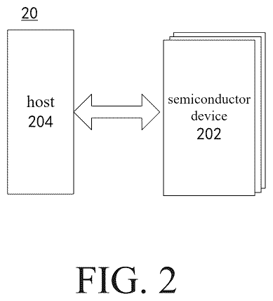

In some possible implementations, FIG. 2 shows a structural diagram of an electronic device 20 having a semiconductor device. As shown in FIG. 2, the electronic device 20 comprises a host 204 and a semiconductor device 202, and the host 204 is coupled to the semiconductor device 202.

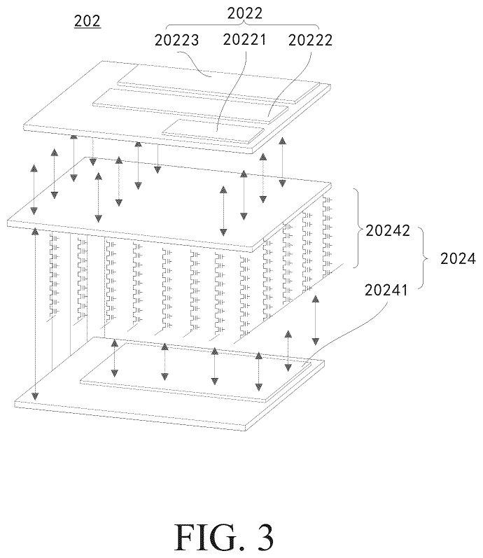

FIG. 3 shows a schematic structural diagram of a semiconductor device, and as shown in FIG. 3, the semiconductor device 202 comprises a processing circuit 2022 and a memory device 2024, and the processing circuit 2022 is coupled to the memory device 2024.

The processing circuit 2022 comprises a controller 20221, a converter 20222, and a processor 20223. The converter 20222 may be a digital-to-analog converter (DAC) or an analog-to-digital converter (ADC). The processor 20223 may comprise, but is not limited to, any one of: a central processing unit (CPU), a graphics processing unit (GPU), and a neural network processing unit (NPU).

The memory device 2024 comprises a peripheral circuit 20241 and a memory cell array 20242, and the peripheral circuit 20241 is coupled to the memory cell array 20242.

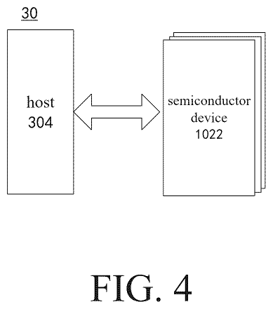

In some possible implementations, FIG. 4 shows a structural diagram of an electronic device 30 having a semiconductor device according to some aspects, and as shown in FIG. 4, the electronic device 30 comprises a host 304 and a semiconductor device 1022, and the host 304 is coupled to the semiconductor device 1022. The function of the processing circuit 1024 in the memory system 102 as shown in FIG. 1 is integrated in the host 304 shown in FIG. 4.

This example is described by taking the electronic device 10 shown in FIG. 1 as an example.

According to some implementations, the processing circuit 1024 is coupled to the semiconductor device 1022 and the host 104, and is configured to control the semiconductor device 1022. The processing circuit 1024 may manage data stored in the semiconductor device 1022 and communicate with the host 104. In some implementations, the processing circuit 1024 is designed to operate in a low duty cycle environment, such as a secure digital (SD) card, a compact flash card (CF) card, a universal serial bus (USB) flash drive, or other medium used in electronic devices such as personal computers, digital cameras, mobile phones, and the like. In some implementations, the processing circuit 1024 is designed to operate in a high duty cycle environment, such as a solid state drive (SSD) or embedded multimedia card (eMMC), which is used as a data storage for mobile electronic devices, such as smart phones, tablets, personal computers, and the like, and an enterprise memory array.

The processing circuit 1024 may be configured to manage data stored in the semiconductor device 1022 and communicate with an external device, such as the host 104. The semiconductor device 1022 is controlled to perform corresponding operations, such as performing data read, data erase, and program operations.

In some implementations, the processing circuit 1024 is further configured to process error correction code (ECC) related to data read from or written to the semiconductor device 1022.

The processing circuit 1024 may also perform any other suitable functions, such as formatting the semiconductor device 1022. The processing circuit 1024 may communicate with an external device (e.g., host 104) according to a particular communication protocol. For example, the processing circuit 1024 may communicate with an external device through at least one of various interface protocols, such as a USB protocol, a multimedia card (MMC) protocol, a peripheral component interconnect (PCI) protocol, a PCI-express (PCI-E) protocol, an advanced technology attachment (ATA) protocol, a serial ATA protocol, a parallel ATA protocol, a small computer system interface (SCSI) protocol, an enhanced small device interface (ESDI) protocol, an integrated drive electronics (IDE) protocol, a Firewire protocol, or the like.

It should be noted that the interface protocol comprises at least one of a USB protocol, an MMC protocol, a peripheral component interconnect (PCI) protocol, a PCI-express (PCI-E) protocol, an advanced technology attachment (ATA) protocol, a serial ATA protocol, a parallel ATA protocol, a small computer system interface (SCSI) protocol, an enhanced small device interface (ESDI) protocol, an integrated drive electronics (IDE) protocol, and a Firewire protocol.

The processing circuit 1024 and the one or more semiconductor devices 1022 may be integrated into various types of memory systems 102, for example, comprised in a same package, such as an embedded multimedia card (eMMC), a universal flash memory (UFS) package, an embedded multi chip package (eMCP) package, or a UFS based multichip package (uMCP) package. The eMMC adopts a unified MMC standard interface to package the high-density NAND and the MMC controller in a ball grid array (BGA) packaging chip. The UFS is an advanced version of the eMMC, and is also an array memory module comprising a plurality of flash memory chips and a controller. The UFS makes up the defect that eMMC supports only half duplex operation (read and write must be performed separately), and can implement full duplex operation, so the performance is doubled. The eMCP is formed by carrying volatile memory, such as static random-access memory (SRAM) or dynamic random-access memory (DRAM) package, on the eMMC.

In an implementation, the DRAM may be a low power double data rate SDRAM (LPDDR). The uMCP is formed by carrying volatile memory (such as SRAM or DRAM) package on the UFS, and has high performance and high capacity. In an implementation, the DRAM may be an LPDDR. For example, the memory system 102 may be implemented and packaged into different types of end electronic devices.

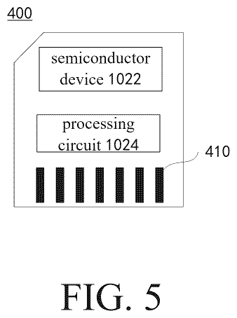

In one example as shown in FIG. 5, a processing circuit 1024 and a single semiconductor device 1022 may be integrated into a memory card 400. The memory card 400 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, and the like. The memory card 400 may also comprise a memory card connector 410 that couples the memory card 400 with a host, such as the host 104 in FIG. 1.

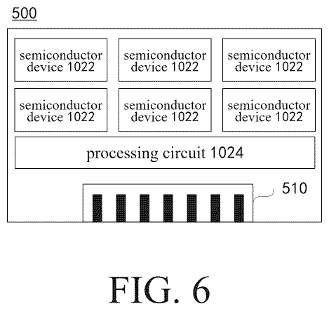

In another example as shown in FIG. 6, a processing circuit 1024 and a plurality of semiconductor devices 1022 may be integrated into an SSD 500. The SSD 500 may also comprise an SSD connector 510 that couples the SSD 500 with a host, such as the host 104 in FIG. 1. In some implementations, the storage capacity and/or operating speed of the SSD 500 is higher than that of the memory card 400.

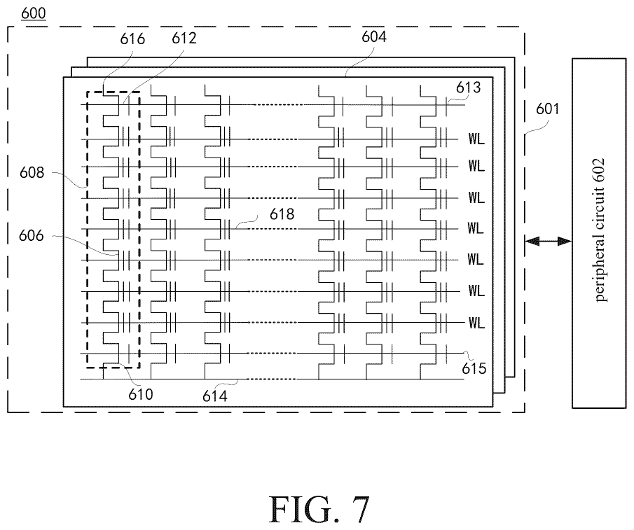

FIG. 7 illustrates a schematic circuit diagram of a semiconductor device 600 example comprising a peripheral circuit 602 according to some aspects of the present disclosure. The semiconductor device 600 may be an example of the semiconductor device 1022 in FIG. 1. The semiconductor device 600 may comprise a memory cell array 601 and a peripheral circuit 602 coupled to the memory cell array 601. The memory cell array 601 may be an array of NAND flash memory cells, where the memory cells 606 are provided in a form of an array of NAND memory strings 608 each extending vertically above a substrate (not shown). In some implementations, each NAND memory string 608 comprises a plurality of memory cells 606 coupled in series and vertically stacked. Each memory cell 606 can maintain a continuous analog value, e.g., voltage or charge, depending on the number of electrons captured within a region of the memory cell 606. Each memory cell 606 may be a floating gate type of memory cell comprising a floating gate transistor, or may be a charge trapping type of memory cell comprising a charge trapping transistor.

In some implementations, each memory cell 606 comprises a single-level cell (SLC) having two possible memory states (levels) and thus capable of storing one bit of data. In an example, each memory cell 606 may be configured to store N bits of data in one of 2N memory states (levels), where N is a natural number greater than 0. The 2N memory states comprise an erase state and 2N-1 non-erase states. In some implementations, each memory cell 606 comprises a single-level cell (SLC) having two possible memory states (levels) and thus may store one bit of data. For example, the first memory state “0” may correspond to a first range of threshold voltages and the second memory state “1” may correspond to a second range of threshold voltages. In some implementations, each memory cell 606 comprises an xLC capable of storing more than one bit of data in more than four memory states (levels). For example, the xLC can store two bits per cell (multi-level cell, MLC), three bits per cell (triple-level cell, TLC), or four bits per cell (quad-level cell, QLC). Each xLC may be programmed to assume a range of possible nominal stored values. In one example, the MLC may be programmed from an erase state to assume one of three possible programmed levels by writing one of three possible nominal stored values (e.g., 01, 10, and 11) to the memory cell 606. The fourth nominal stored value may be used for an erase state (e.g., 00).

As shown in FIG. 7, each NAND memory string 608 may also comprise a source select gate (SSG) transistor 610 at its source terminal and a drain select gate (DSG) transistor 612 at its drain terminal. The SSG transistor 610 and the DSG transistor 612 may be configured to activate a selected NAND memory string 608 (column of the array) during read and program operations. In some implementations, the sources of the NAND memory strings 608 in a same memory block 604 are coupled through a same source line (SL) 614 (e.g., common SL). In other words, according to some implementations, all of the NAND memory strings 608 in a same memory block 604 have an array common source (ACS). According to some implementations, a drain of each NAND memory string 608 is coupled to a respective bit line 616, from which data can be read or written via an output bus (not shown). In some implementations, each NAND memory string 608 is configured to be selected or deselected by applying a select voltage or a deselect voltage to a gate of a respective DSG transistor 612 via one or more DSG lines 613 and/or by applying a select voltage or a deselect voltage to a gate of a respective SSG transistor 610 via one or more SSG lines 615.

As shown in FIG. 7, NAND memory strings 608 may be organized into a plurality of memory blocks 604, each of the memory blocks 604 may have, for example, a common source line 614 coupled to an ACS. In some implementations, each memory block 604 comprises a basic data unit for an erase operation, e.g., all memory cells 606 on the same memory block 604 are erased at a same time. To erase a memory cell 606 in a selected memory block 604, the source lines 614 coupled to the selected memory block 604 and unselected memory blocks 604 in the same plane as the selected memory block 604 may be biased with an erase voltage (Vers), such as a high positive bias voltage (e.g., 20V or higher). The memory cells 606 of adjacent NAND memory strings 608 may be coupled by word lines (WL) 618, the WL 618 selects which row of memory cells 606 are affected by read and program operations.

As shown in FIG. 7, the memory cell array 601 may comprise an array of memory cells 606 in a plurality of rows and columns in each memory block 604. According to some implementations, a column of memory cells corresponds to one NAND memory string 608. A plurality of rows of memory cells 606 may be coupled to word lines 618 respectively, and a plurality of columns of memory cells 606 may be coupled to bit lines 616 respectively.

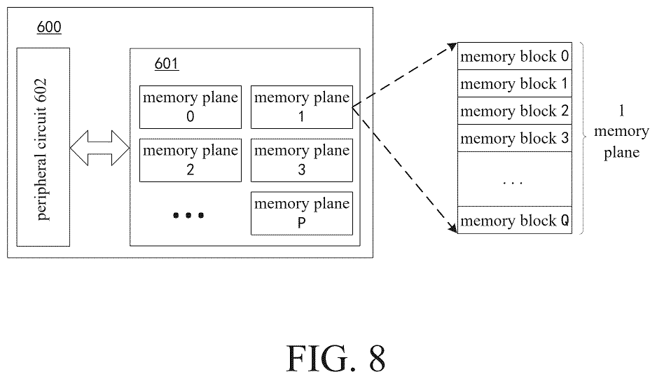

As shown in FIG. 8, the memory cell array 601 may comprise P memory planes (a memory plane 0, a memory plane 1, . . . , a memory plane P), where a memory plane is a minimum unit for implementing integration of the memory cell array 601 on the process of manufacturing. Each memory plane comprises a plurality of memory blocks 604 (a memory block 0, a memory block 1, a memory block 2, a memory block 3, . . . , a memory block Q).

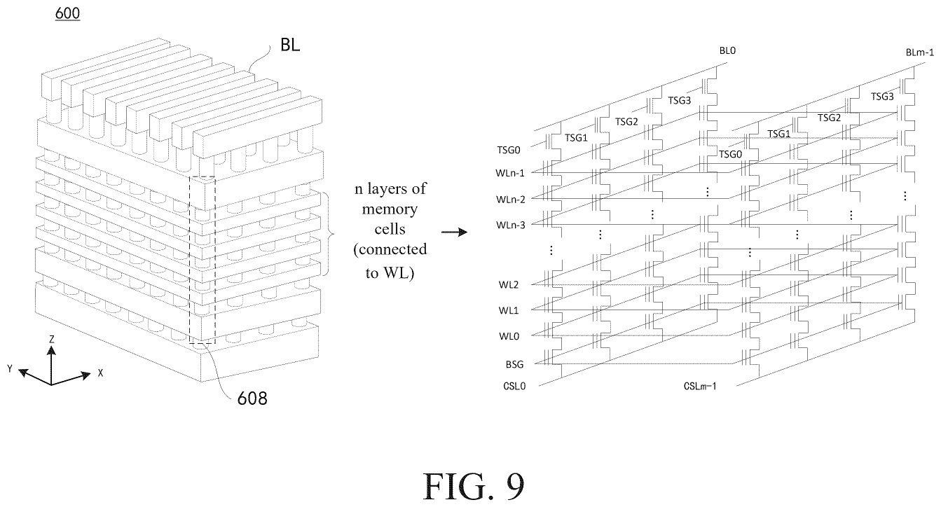

FIG. 9 illustrates a three-dimensional (3D) semiconductor device 600 comprising a multi-layer stack according to some aspects of the present disclosure. As shown in FIG. 9, the semiconductor device 600 comprises a plurality of memory strings 608 and n layers of memory cells (comprising WL0, WL1, WL2, . . . , WLn-1, WLn-2, and WLn-1). The plurality of memory strings 608 comprised in the semiconductor device 600 are arranged along a direction parallel to the bearing surface of the substrate, and the plurality of memory cells in each memory string 608 are arranged along a direction perpendicular to the bearing surface of the substrate. For example, the plurality of memory cells comprised in the semiconductor device 600 are arranged in a three-dimensional array on the substrate, and form a memory cell array.

One end of the memory string 608 is connected to the bit line 616 (comprising BL0, BL2, . . . , BLm-1), and the other end is connected to a common source line (CSL) or an array common source (ACS). The BSG of the memory string 608 may be coupled to the same CSL, or may be coupled to different CSLs (as shown in FIG. 9, CSLO, . . . , CSLm-1), which is not limited herein.

The memory cells 606 in each memory string 608 are also connected to memory cells 606 in other memory strings through word lines 618. For example, if each memory string 608 may comprise 64 memory cells 606, the 3D semiconductor device may comprise 64 word lines 618 WL<63:0>, with each word line 618 connected to a portion of memory cells 606 located in the same layer (e.g., having the same height relative to the substrate). It should be noted that the 64 memory cells 606 are only an example, and the present disclosure is not limited thereto.

In some examples, each memory string 608 may comprise more than 64 (e.g., 128, 196, etc.) memory cells 606. In the 3D semiconductor device 600, the memory cells 606 connected to the same word line 618 is referred to as a memory page, and all memory strings 608 sharing a group of word lines 618 are referred to as a memory block.

The memory string 608 further comprises an upper select transistor connected to the drain of the first memory cell 606, and a lower select transistor connected to the source of the last memory cell 606. The upper select transistor is also referred to as a top select gate (TSG) or a DSG transistor, which comprises TSG0, TSG1, TSG2 and TSG3. The lower select transistor is also referred to as a bottom select gate (BSG) or SSG transistor.

A gate of the TSG is connected to a drain select line (DSL), a source of the TSG is connected to a drain of the first memory cell 606, and a drain of the TSG is connected to the bit line 616.

A gate of the BSG is connected to a source select line (SSL), a drain of the BSG is connected to a source of the last memory cell 606, and a source of the BSG is connected to a source line.

As shown in FIG. 9, the memory cell 606 in the memory string 608 and the memory cells 606 in the other memory strings 608 share a group of word lines 618. Assuming that each memory string 608 comprises m+1 memory cells 606, the 3D semiconductor device may comprise m+1 WL: WL0 to WLm, wherein m comprises an integer greater than 1. Each WL is connected to the memory cells 606 located in the same layer (e.g., having the same height relative to the bearing surface of the substrate). Alternatively, it may be understood that the control gates of the memory cells 606 located in the same layer and the gate connection lines between the control gates form one word line 618.

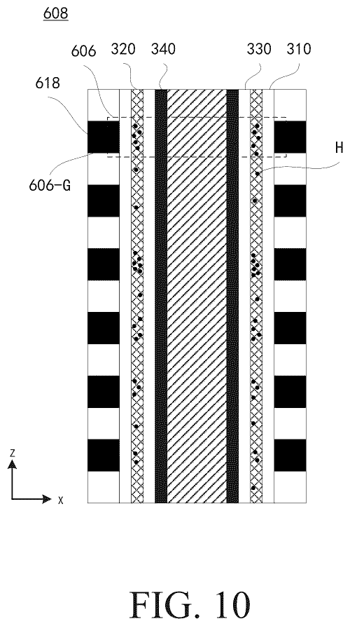

FIG. 10 is a schematic structural cross-sectional view of a memory string 608 according to an implementation of the present disclosure. The memory string 608 comprises a plurality of memory cells 606 disposed in the Z direction. Each memory cell 606 may have the same physical structure. Alternatively, the memory cell 606 may be a charge trapping type of memory cell. For example, the memory cell 606 may comprise a gate 606-G, a block layer 310, a trap layer 320, a tunnel layer 330, and a channel layer 340 (e.g., a poly-si channel). The tunnel layer 330 is located between the trap layer 320 and the channel layer 340.

In some implementations, the material of the trap layer 320 may be, for example, silicon nitride. The material of the tunnel layer 330 comprises silicon oxide, silicon oxynitride, or any combination thereof. The material of the block layer 310 comprises silicon oxide, silicon oxynitride, a high dielectric constant dielectric, or any combination thereof.

In some implementations, the word line 618 may be physically connected to the gate 606-G of the memory cell 606 on the memory string 608, and the word line 618 may also be physically connected to the gates of the memory cells 606 in other memory strings (not shown) and located at the same height (e.g., in Z direction) or at approximately the same height.

When a program operation is performed on the memory cell 606, the trap layer 320 may trap the charge H from the channel layer 340 and penetrating through the tunnel layer 330 according to the tunneling effect under voltage control of the gate 606-G. Depending on the number of charges H in the trap layer 320 of the memory cell 606, the memory cell 606 may have different threshold voltages, thereby being in different program states.

The charges H stored in the trap layer 320 are isolated from other trap layers 320 corresponding to different word lines 618, so that longitudinal diffusion of the charges H in the trap layer 320 along the direction perpendicular to the substrate (not shown) (Z direction) can be suppressed. The suppression of charge diffusion facilitates forming a uniform electrical potential field at the trap layer 320, thereby improving the memory reliability of the trap layer 320, which in turn improves the retention characteristics of the semiconductor device 600.

The number of threshold voltage intervals that the memory cell 606 can achieve is related to the size of data stored in the memory cell 606. For example, the memory cell 606 may be one of an SLC capable of achieving 2 threshold voltage intervals and storing 1 bit data, an MLC capable of achieving 4 threshold voltage intervals and storing 2 bit data, a TLC capable of achieving 8 threshold voltage intervals and storing 8 bit data, or a QLC capable of achieving 16 threshold voltage intervals and storing 16 bit data. The peripheral circuit 602 determines the read data by using the level of the threshold voltage of the memory cell 606.

Referring back to FIG. 7, a peripheral circuit 602 may be coupled to the memory cell array 601 through a bit line (BL) 616, a word line 618, a source line 614, a SSG line 615, and a DSG line 613. The peripheral circuit 602 may comprise any suitable analog, digital, and mixed-signal circuit for facilitating operation of memory cell array 601 by applying and sensing voltages and/or current signals to and from each target memory cell 606 via the bit line 616, the word line 618, the source line 614, the SSG line 615, and the DSG line 613. The peripheral circuit 602 may comprise various types of peripheral circuit formed using metal-oxide-semiconductor (MOS) technology.

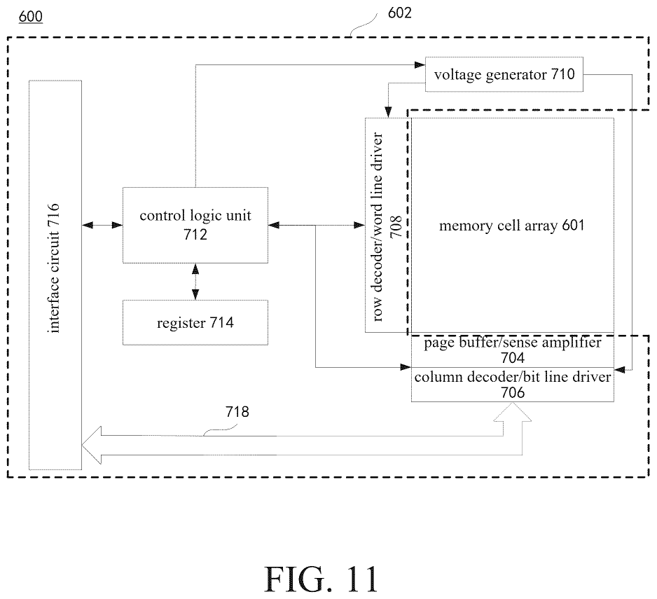

For example, FIG. 11 illustrates some peripheral circuits examples comprising a page buffer/sense amplifier 704, a column decoder/bit line driver 706, a row decoder/word line driver 708, a voltage generator 710, a control logic unit 712, a register 714, an interface circuit (I/F) 716, and a data bus 718. It should be understood that additional peripheral circuit not shown in FIG. 11 may also be comprised.

The page buffer/sense amplifier 704 may be configured to read and program (write) data from and to the memory cell array 601 according to control signals from the control logic unit 712. In one example, the page buffer/sense amplifier 704 may perform a program verify operation to ensure that the data has been properly programmed into the memory cells 606 coupled to the selected word line 618. In yet another example, the page buffer/sense amplifier 704 may also sense a low power signal representing a data bit stored in the memory cell 606 from the bit line 616 in a read operation, and amplify the small voltage swing to an identifiable logic level. As described in detail below and consistent with the scope of the present disclosure, in a program operation, the page buffer/sense amplifier 704 may comprise a memory module (e.g., latch, cache, register, etc.) for temporarily storing a segment of N-bit data received from the data bus 718, and providing the segment of N-bit data to a corresponding target memory cell 606 through a corresponding bit line 616 in each program pass of a multi-pass program operation using a 2N-2N scheme.

The column decoder/bit line driver 706 may be configured to be controlled by the control logic unit 712 and select one or more NAND memory strings 608 by applying a bit line voltage generated by the voltage generator 710. The row decoder/word line driver 708 may be configured to be controlled by the control logic unit 712, and select/deselect a memory block 604 of the memory cell array 601, and select/deselect a word line 618 of the memory block 604. The row decoder/word line driver 708 may also be configured to drive the word line 618 using the word line voltage generated by the voltage generator 710. In some implementations, row decoder/word line driver 708 may also select/deselect and drive SSG line 615 and DSG line 613. The voltage generator 710 may be configured to be controlled by the control logic unit 712 and generate word line voltages (e.g., read voltages, program voltages, pass voltages, local voltages and verify voltages, etc.), bit line voltages, and source line voltages to be provided to the memory cell array 601.

Control logic unit 712 may be coupled to each peripheral circuit described above, and configured to control operations of each peripheral circuit. The register 714 may be coupled to the control logic unit 712 and comprises a status register, a command register, and an address register, for storing status information, command operation code (OP), and command address for controlling operation of each peripheral circuit. The interface circuit 716 may be coupled to the control logic unit 712 and act as a control buffer, to buffer the control commands received from the host (e.g., the host 2000 in FIG. 1) and forward them to the control logic unit 712, and to buffer status information received from the control logic unit 712 and forward it to the host. The interface circuit 716 may also be coupled to the column decoder/bit line driver 706 via a data bus 718, and act as a data input/output (I/O) interface and a data buffer, to buffer and forward data to and from the memory cell array 601.

In practical applications, in the manufacturing and subsequent use processes of the NAND semiconductor device, to ensure stable and reliable operation of the NAND semiconductor device, the processing circuit 1024 may be further configured to manage various functions related to data stored in or to be stored in the semiconductor device 1022, comprising but not limited to bad block management, garbage collection (GC), logical-to-physical address translation, wear leveling, and the like.

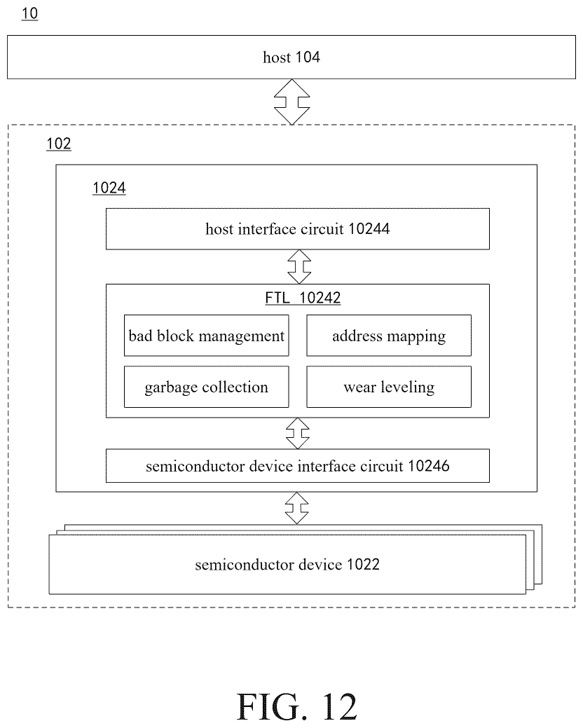

As shown in FIG. 12, a firmware system: a flash translation layer (FTL) 10242 may be implemented in a processing circuit 1024. The performance, reliability, and durability of the memory system 102 (e.g., SSD) depend on the implementation of the algorithm of the FTL 10242. The FTL 10242 may comprise functional modules such as address mapping, garbage collection, wear leveling, bad block management, and power failure recovery. The processing circuit 1024 further comprises a host interface circuit 10244 and a semiconductor device interface circuit 10246. The host interface circuit 10244 is configured to couple the host 104 and the FTL 10242. The semiconductor device interface circuit 10246 is configured to couple the FTL 10242 and the semiconductor device 1022. The semiconductor device interface circuit 10246 comprises a plurality of semiconductor devices 1022 (e.g., a semiconductor device 0, a semiconductor device 1, a semiconductor device 2, . . . , a semiconductor device N, etc.).

Due to the erase-before-write characteristics of the semiconductor device 1022, such as the NAND semiconductor device, for the data writing of the same logical address, it cannot be modified on the basis of the physical address of the original stored data, but only a new physical address may be found to write the updated data. Thus, the FTL 10242 needs to maintain a mapping table of a logical address to a physical address, continuously recording the mapping relationship between the logical address accessed by the host and the physical address in the NAND semiconductor device. For the data that has been updated, the data in the original physical address becomes invalid data, which still occupies the storage space of the NAND semiconductor device, and if the invalid data is not dealt with, the storage space of the NAND semiconductor device will be quickly exhausted. In this regard, the FTL 10242 will perform another important function: garbage collection.

The garbage data is randomly dispersed in each memory block in the NAND semiconductor device, instead of being concentrated in a few certain memory blocks, and in order to improve the efficiency of garbage collection, the memory block with fewer valid data or more invalid data can be selected for collection. Because there is few valid data, there is few data to be moved, so that the speed of emptying the memory block is fast, and the paid cost is low.

In an example, for a NAND semiconductor device, the basic unit for erasing comprises a memory block. One memory block comprises a plurality of physical addresses. Before garbage collection, data in an address storing valid data in the memory block (for example, a source memory block) that is selected to be collected needs to be moved to another idle memory block (target memory block), and then an erase operation is performed on the source memory block.

For example, the memory block after the erase operation is performed is in an erase state or an idle state, and may be marked as a free memory block, and may continue to be configured to perform a corresponding operation, such as performing a program operation on the free memory block.

Due to the upper limit of program/erase times that the memory blocks in NAND semiconductor devices can withstand, the memory blocks have a certain lifespan. If data writing and erase operations are performed on certain memory blocks in a concentrated manner, it will cause rapid damage to these memory blocks and reduce the available space of the NAND. When the available space is reduced to a certain threshold, the NAND semiconductor device will be considered damaged. To extend the lifespan of the NAND semiconductor device, the FTL 10242 needs to evenly distribute data writing and data erase onto individual memory blocks, e.g., wear leveling. Even under the processing by a wear leveling algorithm, a damaged memory block will eventually appear as the memory block wears constantly. The damaged memory block may be replaced with a good memory block in an over provision (OP) in the NAND semiconductor device, or skipped during data writing, and this process is called bad block management.

Bad block management comprises the management for factory bad blocks (FBBs) and grown bad blocks (GBs).

Factory bad blocks are caused by limitations or accidental factors in the manufacturing process during the production of NAND semiconductor devices. They are identified and marked in the production phase, and when a NAND semiconductor device is used, the mark in block in the NAND semiconductor device needs to be scanned first, the bad blocks marked by the manufacturer are picked out, and a bad block table (BBT) is generated. In subsequent use, the blocks within the bad block table will not be selected to avoid causing data errors or loss at the client end.

A grown bad block, which is different from a factory bad block, is gradually formed during normal use of the NAND semiconductor device. This is mainly because frequent erase and write operations result in physical wear of the memory cells, thereby causing data read/write/erase errors. Such a bad block is a reflection of the inherent characteristics of the NAND semiconductor device technology, and needs to be dynamically checked and managed through the BBM mechanism. When the current memory block is detected to become a bad block, the memory block cannot be selected and used again, and is recorded into the BBT.

In some examples, for a grown bad block, with the use of a semiconductor device and with the wear of the semiconductor device, some good memory blocks may become failed memory blocks during use. There are mainly the following cases: (1) when performing a data erase operation, an erase failure state is returned. (2) When performing a data write operation, a data write failure state is returned. (3) When performing a data read operation, if there are too many data errors and the ECC range is exceeded, and after various ways of error checking and correction, such as by performing a read retry, a low density parity check code (LDPC), or by performing a redundant array of independent disks (RAID), the data is still uncorrectable. When any one of the above three cases occurs, the current memory block is considered to become a failed memory block and is recorded into the BBT, and is no longer selected for performing the corresponding operation.

The bad block management comprises two management policies, one is skip policy, and the other one is replace policy.

For the skip policy, according to the established BBT, when performing a data writing operation, upon encountering a bad block registered in the table, the user skips the bad block and write in a next memory block.

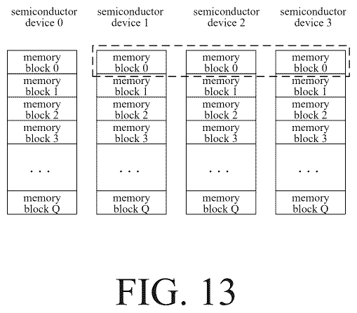

FIG. 13 illustrates 4 semiconductor devices (a semiconductor device 0, a semiconductor device 1, a semiconductor device 2, and a semiconductor device 3) in the memory system 102, and stored data are sequentially written to the 4 semiconductor devices (the semiconductor device 0, the semiconductor device 1, the semiconductor device 2, and the semiconductor device 3). When selecting parallel memory blocks, the memory block number selected by each semiconductor device is the same, and according to the bad block table of the user, if the memory block 0 of the semiconductor device 0 is a bad block, the bad block is not added to the parallel memory block stripe, and the memory block 0 of the semiconductor device 1, the memory block 0 of the semiconductor device 2 and the memory block 0 of the semiconductor device 3 would form a parallel block stripe.

For the skip policy, a bad block is skipped when encountered, the semiconductor device in which the current bad block is located is not used, and the semiconductor devices in which the remaining good memory block are located are used to build a parallel block.

An advantage of the skip policy is that the management is simple, and a bad block is skipped when encountered, but the disadvantage is that the performance is unstable. If N semiconductor devices are concurrent, the parallelism of the system may fluctuate between 1 and N, and the performance may not be guaranteed to be stabilized to be N concurrent dies.

For the replace policy, which is different from the skip policy, the memory blocks in each die are classified into main memory blocks and extra memory blocks, where the extra memory blocks are configured to replace failed memory blocks in the main memory blocks. When a bad block is found on a certain die, the replace policy would replace the failed memory block in the main memory blocks with a certain good memory block in the extra memory blocks in the die. For example, under the replace policy, after encountering the failed memory block, another available free block in the extra memory blocks of the current die is searched for, the replace block is written on, instead of skipping the die.

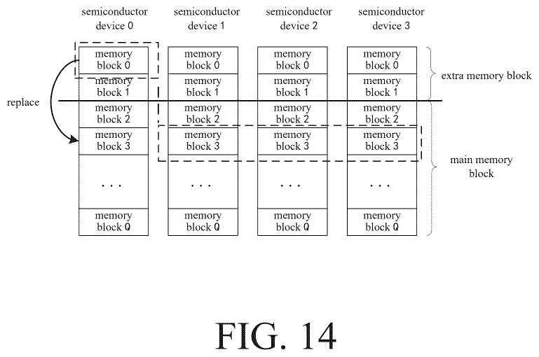

For example, FIG. 14 shows 4 semiconductor devices (a semiconductor device 0, a semiconductor device 1, a semiconductor device 2, and a semiconductor device 3) in the memory system 102, and stored data are sequentially written into the 4 semiconductor devices (the semiconductor device 0, the semiconductor device 1, the semiconductor device 2, and the semiconductor device 3). If the memory block 3 of the semiconductor device 0 is a bad block, the failed memory block 3 of the semiconductor device 0 is replaced with the memory block 0 (or the memory block 1) in the extra memory block in the semiconductor device 0. The memory block 0 of the semiconductor device 0, the memory block 3 of the semiconductor device 1, the memory block 3 of the semiconductor device 2, and the memory block 3 of the semiconductor device 3 then form a parallel block stripe.

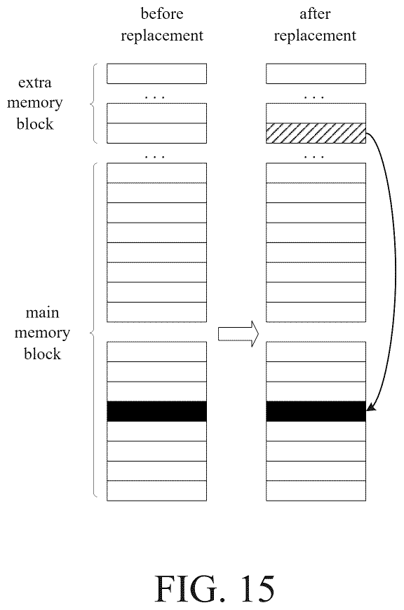

As shown in FIG. 15, a failed memory block (a black block in the figure) in the main memory block is replaced with a memory block (a block filled with diagonal lines in the figure) in the extra memory block.

Replace policy exhibit significant advantages in ensuring that N dies operate simultaneously and improving performance stability. At the same time, this policy is not constrained by the physical address for the supplementary operation of the FBB/GBB, and is able to flexibly map the extra memory block to any position of the logical address space to quickly replace the damaged memory block.

However, although the replace policy is flexible, when the physical address of the failed memory block is far away from the physical address of the memory block used for replacement, due to the parasitic resistance of the semiconductor device, the long power supply wiring path introduces additional voltage drop, making the voltage drop more severe, and significantly exacerbating the voltage drop (IR Drop) problem, which affects the performance of the NAND semiconductor device.

Voltage drop, which is an inevitable voltage loss phenomenon when a current passes through a resistor, is particularly critical in NAND semiconductor devices. Particularly when performing large-scale data read, write, or erase operations, current demand surges and varies with the locations of memory cells in the array, as the parasitic resistance varies at different locations. For cells at the far end of the array, elements such as metal wires, transistors and the like in the chip generate significant voltage loss due to the resistance effect. Such voltage drop not only affects the voltage stability of each region inside the NAND semiconductor device, but also can directly weaken the overall performance and functional reliability of the chip. For example, the voltage drop may cause insufficient voltages for data read, write, or erase operations, causing the corresponding operation unsuccessful.

Further, there is a close association between the specific location of the memory block in the NAND semiconductor device and the voltage drop. Due to differences in physical layout of the memory blocks at different locations, and in particular, with different lengths of the additional wirings, the changes in current distribution and the resistance effect would be caused, so that each memory block is affected differently when facing the voltage drop. The different voltage drop effects may ultimately manifest in a decrease in the read and write performance of the memory block and fluctuations in stability.

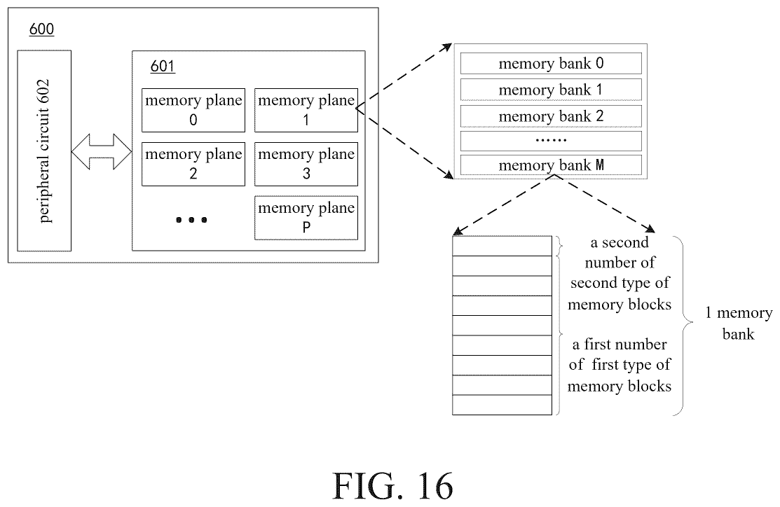

To resolve one or more of the above problems, the structure of the memory cell array 601 shown in FIG. 8 may be improved, as shown in FIG. 16. The M memory blocks in the memory plane are configured to a plurality of memory banks, and at a memory bank-level, each of the memory banks comprises a first number of a first type of memory blocks and a second number of a second type of memory blocks, where the first type of memory blocks may be working memory blocks (or main memory blocks), and the second type of memory blocks may be extra memory blocks. The second type of memory blocks may be configured to replace a failed memory block in the first type of memory blocks.

For example, each of the memory banks comprises m+n (for example, the first number is n, and the second number is m) memory blocks, and any n (for example, the first number) of the m+n memory blocks are configured as working memory blocks. When a corresponding operation (such as a write operation, a read operation, an erase operation or a compute-in-memory operation, and the like) is performed at a memory bank, the n memory blocks are selected in each memory bank each time to perform a corresponding operation. Any m (for example, the second number) of the m+n memory blocks are configured as extra memory blocks to replace failed memory blocks in a memory bank, to ensure that at least n normal memory blocks in each memory bank are configured as working memory blocks to perform a corresponding operation. If a number of normal memory blocks in a memory bank is less than n, the memory bank is marked as a failed memory bank and is not configured to perform a corresponding data operation.

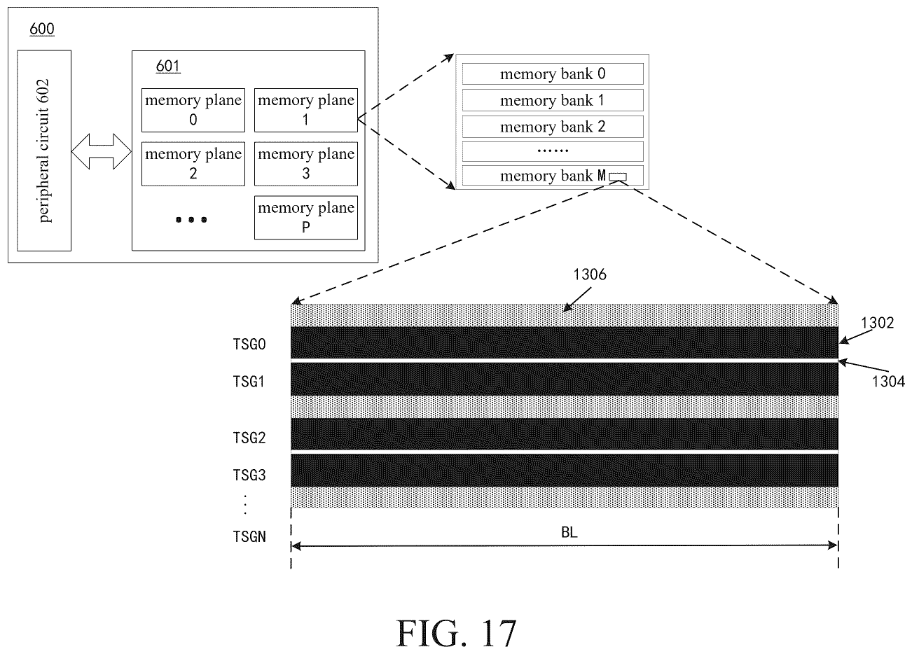

As shown in FIG. 17, P memory planes (a memory plane 0, a memory plane 1, a memory plane 2, a memory plane 3, . . . and a memory plane P) in the memory cell array 601 are shown, and each memory plane comprises a plurality of memory banks (a memory bank 0, a memory bank 1, a memory bank 2, . . . and a memory bank M). Each memory bank comprises a plurality of TSGs (a TSG0, a TSG1, a TSG2, a TSG3, . . . , a TSGN). Each TSG is coupled to a gate-line 1302 of an upper select transistor of the memory string 608, and a TSG slit 1304 is formed between the TSGs to cut off (or isolate) the TSG. A gate-line slit 1306 is formed at a position adjacent to the TSG, and is configured to cut off (or isolate) the metal layer corresponding to the gate line of the upper select transistor of the memory string 608 in the memory cell array 601.

For example, the TSG may be a coarse TSG. Each memory bank may comprise a 16 KB bit line BL.

In order to limit the size of the relative physical address span between the memory blocks in the same memory bank, during designing, when configuring memory blocks for each memory bank, it is ensured that a physical distance between any two of the m+n memory blocks comprised in each memory bank is less than a threshold. Meanwhile, it is ensured that a difference between a physical address of any failed memory block and a physical address of any normal memory block in a same memory bank is less than a threshold.

In the solution disclosed in the present disclosure, in each memory bank, it is not necessary to specify which m memory blocks in the memory bank are the m extra memory blocks, or which n memory blocks in the memory bank are the n main memory blocks. When in use, n normal memory blocks are selected from (n+m) memory blocks in each memory bank to perform a corresponding operation. By distributing the extra memory blocks into each memory bank, the relative physical address spans between the memory blocks in the same memory bank are relatively small and relatively fixed, so the variation of the current distribution and the resistance effect can be reduced, and correspondingly, the threshold voltage (Vt) distribution is more converged.

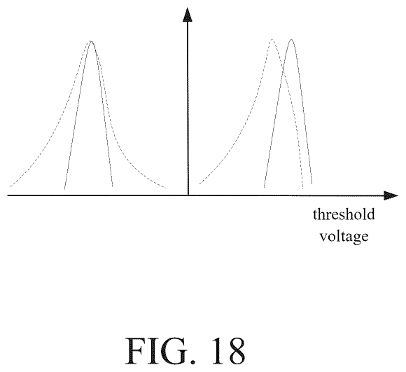

As shown in FIG. 18, any two of the multiple program states are shown, where the threshold voltage distribution shown by the dashed line corresponds to the threshold voltage distribution before the present solution is implemented, and the threshold voltage distribution shown by the solid line corresponds to the threshold voltage distribution after the present solution is implemented.

According to the solution disclosed by the present disclosure, by reducing the influence of the voltage drop on the read-and-write performance of the memory block, the read-and-write performance, stability and reliability of the memory block are improved. Meanwhile, since the n working memory blocks are selected from the m+n memory blocks, the corresponding data operations are relatively evenly distributed to the n memory blocks of the m+n memory blocks, so that wear leveling is achieved, and the lifespan of the semiconductor device is prolonged.

For the structure of the memory cell array 601 as shown in FIG. 16, in some scenarios, a probability that a bad block is generated in the semiconductor device 600 may be relatively small, and a probability that bad blocks are generated in all of a plurality of memory banks is even smaller. If m extra memory blocks are configured for each memory bank, the utilization of the memory space of the semiconductor device may be relatively low, resulting in problems such as a relatively high cost of the hardware material.

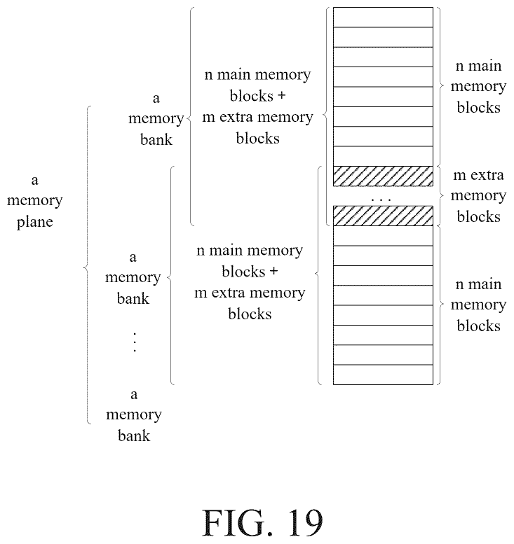

In order to improve the utilization efficiency of the memory space and reduce the cost of the hardware material, in some possible implementations, as shown in FIG. 19, the memory cell array 601 may be configured such that at least two memory banks share m extra memory blocks (m is greater than or equal to 1). Any one of the m extra memory blocks can only be configured to replace a failed memory block in one memory bank at a same time.

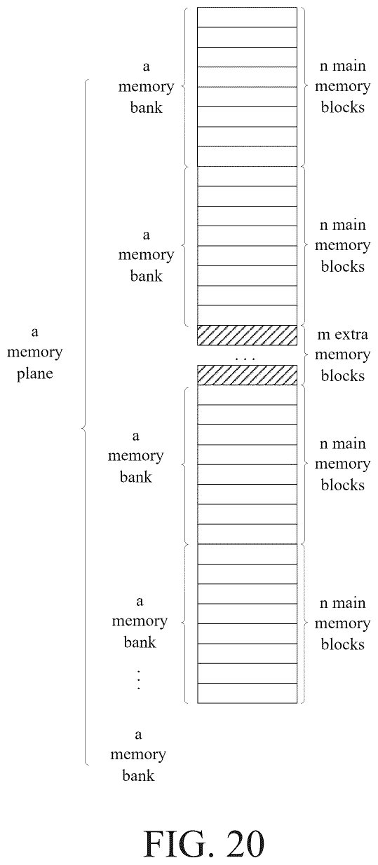

In some examples, as shown in FIG. 20, the memory cell array 601 may be configured such that four memory banks share m extra memory blocks. Each of the memory banks comprises n main memory blocks.

In order to accurately determine the relative physical location of a memory bank level extra memory block, for example, no replacement of the failed memory block is performed by selecting extra memory block across the memory banks, the address decoding (X-Dec) is performed in a two-level decoding manner of memory bank-level and memory block-level.

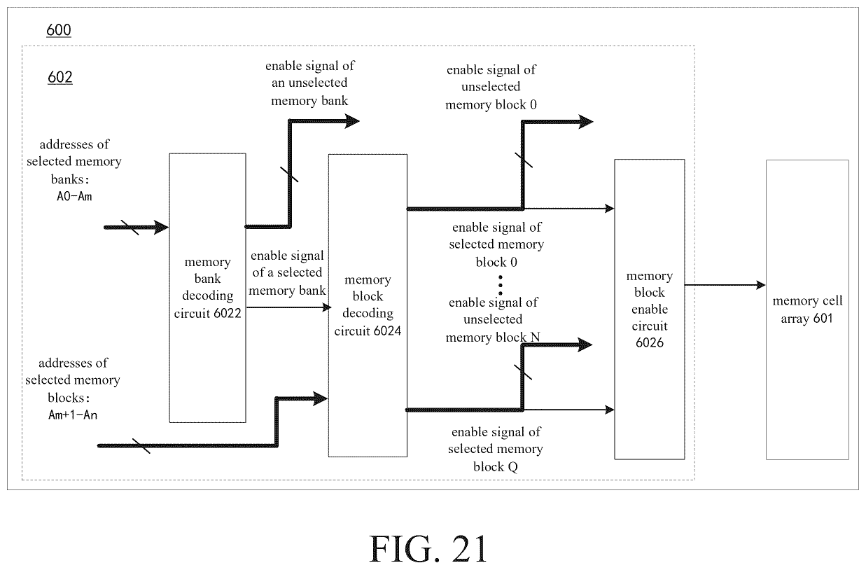

FIG. 21 shows a schematic structural diagram of a semiconductor device. A peripheral circuit 602 in the semiconductor device 600 comprises a memory bank decoding circuit 6022, a memory block decoding circuit 6024 and a memory block enable circuit 6026 coupled in sequence. A memory cell array 601 may be the memory cell array 601 as shown in FIG. 16.

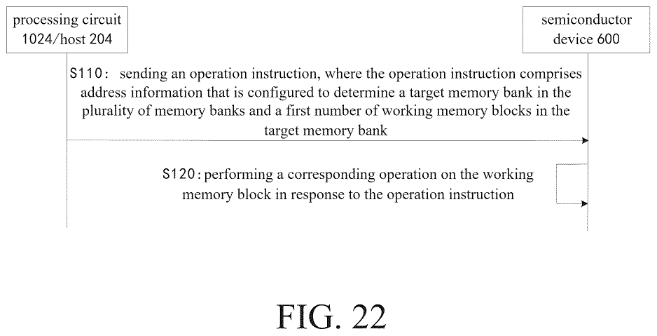

The operating method as shown in FIG. 22 may be implemented based on the semiconductor device 600 shown in FIG. 21, comprising operations S110-S120:

S110: sending an operation instruction, where the operation instruction comprises address information that is configured to determine a target memory bank in the plurality of memory banks and a first number of working memory blocks in the target memory bank.

In some possible examples, the operation instruction may be sent by the processing circuit 1024 in FIG. 1, FIG. 5, and FIG. 6, or sent by the host 304 in FIG. 4, and the semiconductor device (such as the semiconductor device shown in FIG. 1, FIG. 4, FIG. 5, and FIG. 6) may receive the operation instruction.

In some examples, the address information may comprise A0−Am and Am+1−An, where A0−Am is configured to determine the location of the target memory bank, for example, the address of the selected memory bank, and the address A0−Am of the selected memory bank is parsed by the memory bank decoding circuit 6022. Am+1−An is configured to determine the location of the working memory block in the target memory bank, for example, the address of the selected memory block. The address Am+1−An of the selected memory block is parsed by the memory block decoding circuit 6024, to ensure that the selected memory blocks are the memory blocks in the same memory bank, and avoid selecting memory blocks across the memory banks.

The memory bank decoding circuit 6022 receives the address signal A0−Am and selects one or more memory banks to access according to the address signal. A selected memory bank enable signal is sent to the memory block decoding circuit 6024, and when the selected memory bank enable signal is activated, it allows corresponding operations to be performed on the data in the memory bank.

The memory block decoding circuit 6024 receives the address signal Am+1−An, selects a specific memory block in the selected memory bank according to the address signal, and sends an enable signal to the selected memory block in the memory cell array 601 through the memory block enable circuit 6026 to activate the selected memory block. For example, the memory block 0 (or the memory block Q) in the memory bank 0 (shown in FIG. 16) is selected, and the memory block 0 (or the memory block Q) in the memory bank M (shown in FIG. 16) is not selected.

In FIG. 21, the selected memory bank and the selected memory block represent the particular memory bank and memory block that are selected based on the control of the memory bank decoding circuit 6022, the memory block decoding circuit 6024, the memory block enable circuit 6026 and the enable signal described above. These selected memory banks and memory blocks may then perform corresponding data operations (e.g., data read, data write, data erase, and compute-in-memory operations). The unselected memory bank and the unselected memory block represent that there are no corresponding enable signals activated, and will keep in an inactive state and not participate in performing corresponding data operations.

S120: performing a corresponding operation on the working memory block in response to the operation instruction.

In some examples, the corresponding operation may comprise, but are not limited to, writing the storing data to the target memory bank, reading the stored data from the target memory bank, erasing the stored data in the target memory bank, and the like.

The semiconductor device in the implementations corresponding to FIG. 16, FIG. 17 and FIG. 21, and the semiconductor device in the implementations corresponding to FIG. 1, FIG. 2, FIG. 3, FIG. 4, FIG. 5, FIG. 6, FIG. 7, FIG. 8, FIG. 9 and FIG. 11 may be applied to a compute-in-memory device after processed by the implementations corresponding to FIG. 16, FIG. 17 and FIG. 21.

At present, most computing platforms are based on a von Neumann's architecture. Von's architecture is compute-centric, where a computation module and a memory module are separated, and the two coordinate to complete operation and accessing of data. However, because the computation module (for example, the processor, which may be disposed in the processing circuit 1024 or the host 104, not shown in the figure) is designed to mainly improve the computation speed, while the memory module is more focus on capacity improvement and cost optimization, the performance is mismatched between “memory” and “computation”, which leads to problems such as low memory access bandwidth, long latency, high power consumption and the like, for example, the commonly referred “memory wall” and the “power consumption wall”. The more intensive the memory access is, the more serious the problem of “wall” will be, and the more difficult to increase the computing power will be. With the rapid rise of memory access intensive applications represented by artificial intelligence, such as a convolutional neural network (CNN), a recurrent neural network (RNN), and the like, memory access latency and power consumption costs cannot be ignored, and the reform of a computing architecture is particularly urgent.

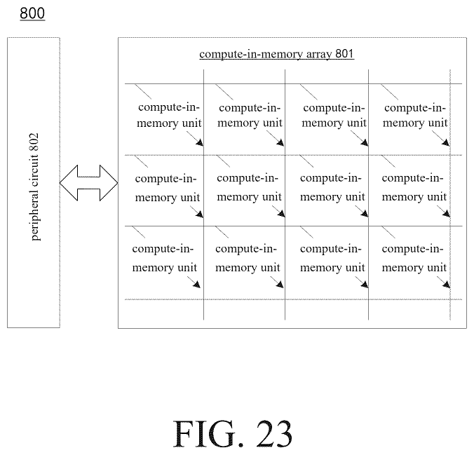

The core of the compute-in-memory (CIM) architecture, as a new computing architecture, is to fully fuse the memory and computation, and can effectively overcome the bottleneck of the von Neumann's architecture, and an order of magnitude increase in computational energy efficiency can be achieved. For the compute-in-memory, in the chip design process, the memory cell and the computation unit are no longer distinguished, and the fusion of memory and computation is truly realized. The essence of compute-in-memory is to utilize the physical characteristics of different storage media to redesign the storage circuit to make it have both computing and storage capabilities, thereby directly eliminating the boundary between “storage” and “computing”, and achieving the goal of improving computing energy efficiency by orders of magnitude. FIG. 23 shows a structural diagram of a compute-in-memory device. The compute-in-memory device 800 comprises a compute-in-memory array 801 and a peripheral circuit 802, and the compute-in-memory array 801 is coupled to the peripheral circuit 802. The compute-in-memory array 801 is configured to store weight matrix data. The compute-in-memory array comprises compute-in-memory cells arranged in rows and columns, and these cells may perform various computation operations, such as matrix operation and vector operation, according to a preset algorithm.

Compared with the von Neumann's architecture, the compute-in-memory architecture has the advantages of high operation speed, low power consumption, high integration density and the like. The compute-in-memory fuses the computation function into the memory cell, so the frequent migration of the data between the data memory module and the computation module is reduced, and the delay of data transmission is also reduced. In addition, the compute-in-memory integrates the computation and memory functions on the same chip, so the external connection and wiring requirements are reduced, so that the integration level of the chip is higher, and the chip can be applied to smaller and lighter electronic devices.

An artificial intelligence algorithm represented by a neural network relates to various tensor and vector computation, where most representative operators are matrix vector multiplication. These operators have the characteristics of large data volume, large computation volume and high parallelism requirement. When a processor in a computing platform based on a von Neumann's architecture executes an artificial intelligence algorithm, due to the separation of memory and computation, a large amount of data migration exists between the memory and the arithmetic unit, causing huge power consumption and delay costs, which results in that the power consumption of data migration is far higher than the computing power consumption, and this becomes a bottleneck of the development of the von Neumann's architecture accelerator. The core idea of the compute-in-memory technology is to fuse the memory with the arithmetic unit together. By storing the relatively fixed weight matrix data in the memory and inputting the input feature vector into the array, the matrix-vector multiplication computation is performed in the memory, so the migration of a large amount of weight data is effectively avoided while the high parallel data access and computation are completed, thereby achieving the purpose of improving the operation speed and the energy efficiency. Therefore, the compute-in-memory is very suitable for accelerating the matrix and vector operation in the artificial intelligence algorithm.

In some examples, the compute-in-memory array 801 may be configured to perform a matrix-vector multiplication operation as shown in the equation (1), where V_{IN0}, V_{IN1}, . . . , V_{INN} represent the operation data (or input vector) input into the compute-in-memory array 801. Taking image recognition applications as an example, the operation data may be image feature information. W₀₀, W₀₁, . . . , W_{0M}, W₁₀, W₁₁, . . . , W_{1M}, . . . W_{N0}, W_{N1}, . . . , W_{NM} etc. represent the weight matrix data stored in the compute-in-memory array 801. The weight matrix data is composed of weight data (for example, for a flash memory, the weight data can be represented by the threshold voltage of memory cells in NAND or NOR; for a RRAM device, it may be represented by the conductance of memory cells. This example is illustrated using NAND as an illustrative example). Equations (2), (3) and (4) are used to represent an operation result of multiplying and accumulating the operation data and the weight matrix data.

$$[ {V}_{IN 0} , {V}_{IN 1} , … , {V}_{INN} ] * [ \begin{matrix}{w}_{00} , {w}_{01} , … , {w}_{0 M} \\ {w}_{10} , {w}_{11} , … , {w}_{1 M} \\ … \\ {w}_{N 0} , {w}_{N 1} , … , {w}_{NM}\end{matrix} ] = [ {I}_{D 0} , {I}_{D 1} , … , {I}_{DM} ] \qquad equation ( 1 )$$

$${I}_{D 0} = {V}_{IN 0} * {w}_{00} + {V}_{IN 1} * {w}_{10} + ⋯ + {V}_{INN} * {w}_{N 0} \qquad equation ( 2 )$$

$${I}_{D 1} = {V}_{IN 0} * {w}_{01} + {V}_{IN 1} * {w}_{11} + ⋯ + {V}_{INN} * {w}_{N 1} \qquad equation ( 3 )$$

$$…$$

$${I}_{DM} = {V}_{IN 0} * {w}_{0 M} + {V}_{IN 1} * {w}_{1 M} + ⋯ + {V}_{INN} * {w}_{NM} \qquad equation ( 4 )$$

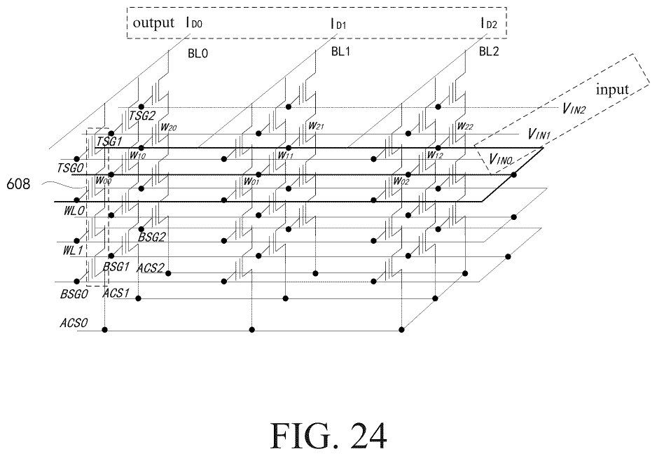

FIG. 24 shows an example of a matrix-vector operation when the semiconductor device 600 is used as a compute-in-memory device 800, as shown in equation (5) to equation (9):

$$[ \begin{matrix}{V}_{IN 0} & {V}_{IN 1} & {V}_{IN 2}\end{matrix} ] * [ \begin{matrix}{w}_{00} & {w}_{01} & {w}_{02} \\ {w}_{10} & {w}_{11} & {w}_{12} \\ {w}_{20} & {w}_{21} & {w}_{22}\end{matrix} ] = [ \begin{matrix}{I}_{D 0} & {I}_{D 1} & {I}_{D 2}\end{matrix} ] \qquad equation ( 5 )$$

$${I}_{D 0} = {V}_{IN 0} * {w}_{00} + {V}_{IN 1} * {w}_{10} + {V}_{IN 2} * {w}_{20} \qquad equation ( 6 )$$

$${I}_{D 1} = {V}_{IN 1} * {w}_{01} + {V}_{IN 1} * {w}_{10} + {V}_{IN 1} * {w}_{20} \qquad equation ( 7 )$$

$${I}_{D 2} = {V}_{IN 0} * {w}_{01} + {V}_{IN 1} * {w}_{11} + {V}_{IN 2} * {w}_{21} \qquad equation ( 8 )$$

$${I}_{D 2} = {V}_{IN 0} * {w}_{02} + {V}_{IN 1} * {w}_{12} + ⋯ + {V}_{IN 2} * {w}_{22} \qquad equation ( 9 )$$

where the process of writing the weight data W₀, W₀₁, W₀₂; W₁₀, W₁₁, W₁₂; W₂₀, W₂₁, W₂₂ into the semiconductor device 600 is completely consistent with the program process of the memory cell array 601. The operation data (or input vector) V_{IN0}, V_{IN1}, V_{IN2} is input to the gates of TSG0, TSG1, TSG2 respectively, and the operation data (output data or output vector) I_{D0}, I_{D1}, I_{D2} is output from bit lines BL0, BL1 and BL2 respectively.

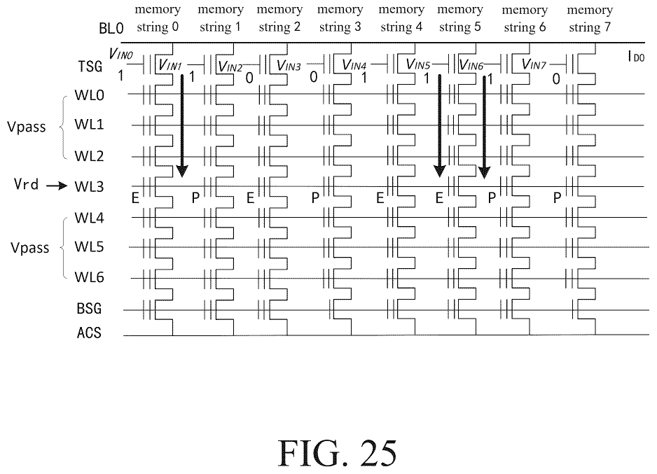

FIG. 25 shows a basic principle of a compute-in-memory operation. As shown in FIG. 25, seven word lines (WLs) WL0, WL1, WL2, WL3, WL4, WL5, and WL6 are shown in the memory cell array 601, and eight memory strings (str) of memory string 0 (str0), memory string 1 (str1), memory string 2 (str2), memory string 3 (str3), memory string 4 (str4), memory string 5 (str5), memory string 6 (str6), and memory string 7 (str7) are shown.

The memory cell may be, but is not limited to, configured to be SLC, MLC, TLC and QLC memory cells, and this example takes the memory cell for storing the weight array data being configured to be an SLC memory cell as an example, for example, each memory cell may have two states, an erase state E, or a program state P. The erase state E may indicate that the data stored in the current memory cell is 1, denoted as E(1). The program state P may indicate that the data stored in the current memory cell is 0, denoted as P(0).

As shown in Table 1, the relationship between operation data (Vin) of the input, the weight data (weight, e.g., the threshold voltage Vth of the memory cell) in the memory cell, and the operation result (such as the bit line (BL) current) output by the memory cell array 601 is shown.

TABLE 1

| Operation | Weight | Operation |
|---|---|---|
| Data (Vin) | Data (weight) | Results (output) |
| 1 | E(1) | 1 |
| 1 | P(0) | 0 |
| 0 | E(1) | 0 |
| 0 | P(0) | 0 |

During the compute-in-memory operation, a read voltage Vrd is applied on the selected word line WL (program word line, the memory cell thereon stores weight data) to activate the weight data stored in the memory cell coupled to the selected word line WL, and the turn-on voltage Vpass is applied to the other WLs. An input voltage (operation data or input vector) is applied on the top select gate TSG. The output current is collected at the BL terminal or the SL terminal, and after the output currents of all the memory cells are collected, the addition is achieved through accumulation.

For example, as shown in FIG. 25, taking the weight data stored in the memory cells of the word line WL3 being E(1), P(0), E(1), P(0), E(1), E(1), P(0), and P(0) as an example. If a read voltage Vrd is applied to the word line WL3 in the compute-in-memory array 801 as shown in FIG. 25, and input voltages V_{IN0}=1, V_{IN1}=1, V_{IN2}=0, V_{IN3}=0, V_{IN4}=1, V_{INS}=1, V_{IN6}=1, V_{IN7}=1 are applied to the top select gates TSGs, then:

$${I}_{D 0} = 1 * E ( 1 ) + 1 * P ( 0 ) + 1 * E ( 1 ) + 1 * P ( 0 ) + 1 * E ( 1 ) + 1 * E ( 1 ) + 1 * P ( 0 ) + 1 * P ( 0 )$$

Therefore, the process of performing the vector-matrix multiplication and addition operation by the compute-in-memory device is equivalent to the operation of reading the current when given the voltage in the memory cell array 601. The memory string 0, memory string 4, and memory string 5 contribute currents in the current I_{D0}.

A small fluctuation of the voltage during in-memory computation in the compute-in-memory device may cause a deviation of the computation result, especially in a in-memory computation scenario that requires high accuracy. In view of the strict requirement of the accuracy of the in-memory computation on the voltage drop (IR Drop), the semiconductor device in the implementations corresponding to FIG. 16, FIG. 17 and FIG. 21 may be applied to a compute-in-memory device, so as to reduce the influence of the voltage drop on the accuracy of the in-memory computation.

In the schematic diagram of the semiconductor device shown in FIG. 21, if the memory block in the semiconductor device 600 is configured for a normal memory operation (for example, data write, data read, or data erase), only one memory block needs to be selected for operation each time. However, if the memory block in the semiconductor device 600 is configured to perform an in-memory computation operation, a plurality of memory blocks need to be selected each time (because the operation data received by one memory block is limited). The selected memory block address comprises the addresses of the plurality of memory blocks, and the memory block decoding circuit 6024 needs to perform decoding for multiple times, and outputs a plurality of high-level memory block enable signals to activate the selected memory blocks. Therefore, when the memory blocks in the semiconductor device 600 are configured to perform the compute-in-memory operation, the circuit requirements are complex, the operation is inconvenient, and the power consumption is large.

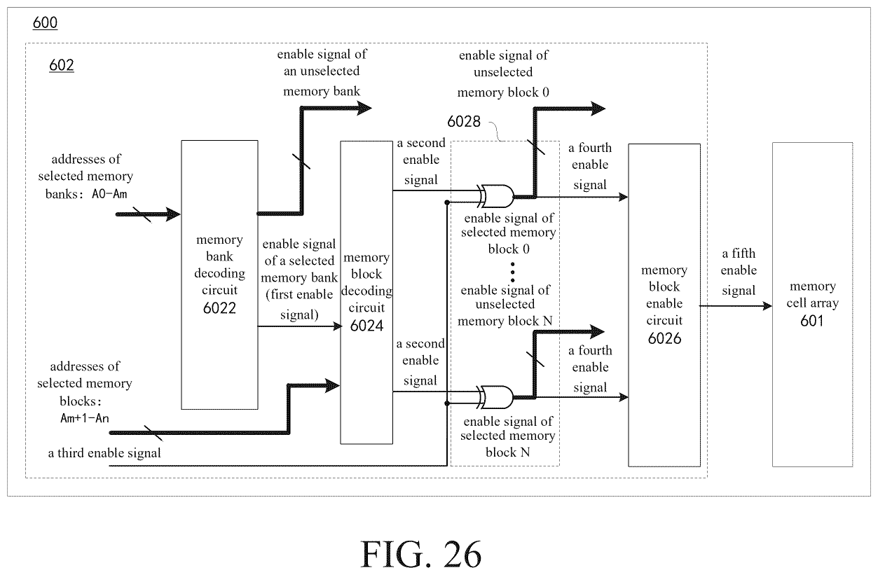

In order to reduce complexity and power consumption of the circuit and facilitate operation, the present disclosure improves the circuit shown in FIG. 21, as shown in FIG. 26. In a semiconductor device 600 as shown in FIG. 26, an XOR logic circuit 6028 is added to reduce complexity and power consumption of the circuit, and a flexible selection of a plurality of memory blocks is achieved by performing an inverse selection operation of the XOR logic circuit 6028. In an implementation, the memory block is controlled to perform a normal memory operation or perform a compute-in-memory operation by a compute-in-memory enable signal.

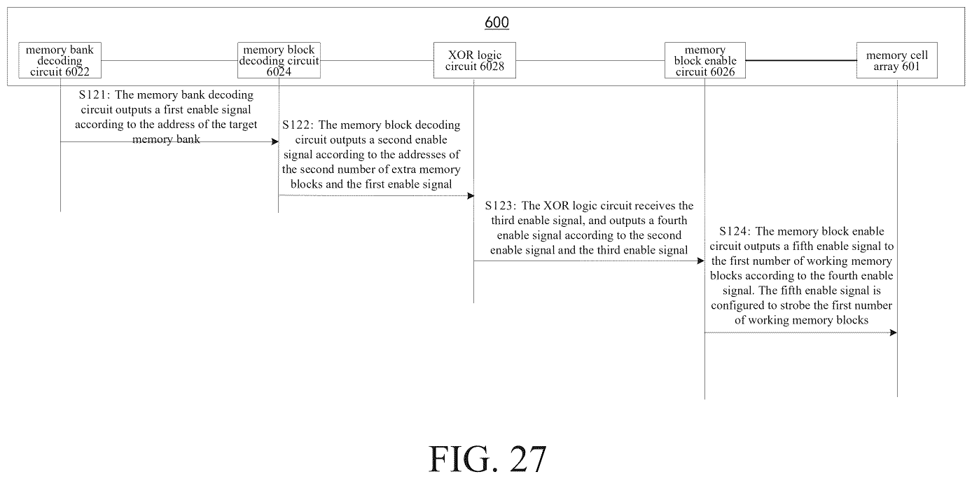

In some possible implementations, taking the example that address information comprises the address of a target memory bank and the addresses of the second number of extra memory blocks, in the semiconductor device 600 as shown in FIG. 26, the operating method of the semiconductor device comprising the following operations S121-S124 as shown in FIG. 27 may be implemented, and the operations comprise:

S121: The memory bank decoding circuit outputs a first enable signal according to the address of the target memory bank.

For example, the memory bank decoding circuit 6022 outputs the first enable signal (e.g., the enable signal of the selected memory bank) according to the address of the target memory bank (e.g., the address of the selected memory bank: A0−Am).

S122: The memory block decoding circuit outputs a second enable signal according to the addresses of the second number of extra memory blocks and the first enable signal.

S123: The XOR logic circuit receives the third enable signal, and outputs a fourth enable signal according to the second enable signal and the third enable signal.

In some examples, the fourth enable signal comprises an XOR result of the second enable signal and the third enable signal. The third enable signal may be carried in operation instruction. The processing circuit 1024 shown in FIG. 1, FIG. 5, or FIG. 6, or the semiconductor device 202 shown in FIG. 2 and FIG. 3, or the host 304 shown in FIG. 4, the processing circuit 1024, the semiconductor device 202, or the host 304 may control the level of the third enable signal to control the semiconductor device 600 shown in FIG. 26 to perform different operations (data write, data read, data erase, or in-memory computation).

In an example, if the third enable signal is at a low level, the memory block performs a normal memory operation. At this time, the memory block decoding circuit 6024 outputs a high level enable signal to the selected memory block. After the high level enable signal passes through the XOR logic circuit 6028, the XOR logic circuit 6028 outputs a high level, and the selected memory block is activated for normal memory operation (data write, data read or data erase).

For example, the operation instruction may comprise a sixth enable signal (a enable signal when the third enable signal is at a low level). The sixth enable signal is configured to indicate that the target memory bank is configured to perform a data memory operation. The data memory operation may comprise, but is not limited to, writing the storing data to the target memory bank, reading the stored data from the target memory bank, and erasing the stored data in the target memory bank.

In another example, if the third enable signal is at a high level, the XOR logic circuit 6028 implements an inverse selection operation, and the memory block performs a compute-in-memory operation. At this time, the memory block decoding circuit 6024 outputs a high level enable signal to the selected memory block, and after the high level enable signal passes through the XOR logic circuit 6028, the XOR logic circuit 6028 outputs a low level, and the selected memory block is in an inactive state, while the unselected memory block is in the active state for the compute-in-memory operation.

For example, the operation instruction further comprises a seventh enable signal (a enable signal when the third enable signal is at a high level). The seventh enable signal is configured to indicate that the target memory bank is configured to perform a compute-in-memory (in-memory computation) operation. In the implementations as shown in FIG. 23, FIG. 24, and FIG. 25, in response to the operation instruction, the peripheral circuit 802 inputs the operation data to the first number of working memory blocks to obtain an operation result. The operation result comprises an operation result of the operation data and the stored data in the working memory block.

In the above implementations, both the second enable signal and the third enable signal are at high levels, and after passing through the XOR logic circuit 6028, the fourth enable signal output by the XOR logic circuit 6028 is at a low level. The selected second number of extra memory blocks (which may comprise a failed memory block) are in an inactive state, and the unselected first number of working memory blocks are in an active state for performing a corresponding operation. The number of the second number of extra memory blocks is less than the number of the first number of working memory blocks. The control logic of the semiconductor device 600 shown in FIG. 26 is simplified by the inverse selection operation of the XOR logic circuit 6028.

S124: The memory block enable circuit outputs a fifth enable signal to the first number of working memory blocks according to the fourth enable signal. The fifth enable signal is configured to strobe the first number of working memory blocks.

For example, as shown in FIG. 24 and FIG. 25, the working memory block comprises select lines (for example, TSG) and memory strings. The memory string comprises a plurality of transistors. Drain lines and source lines of the plurality of transistors are alternately coupled to each other, and the select line is coupled to a gate line of a transistor at one end of the memory string. In response to the operation instruction, the peripheral circuit inputs the operation data (for example, V_{IN0}=1, V_{IN1}=1, V_{IN2}=0, V_{IN3}=0, V_{INA}=1, V_{IN5}=1, V_{IN6}=1, V_{IN7}=1) to the select lines in the working memory blocks to obtain an operation result, as follows:

$${I}_{D 0} = 1 * E ( 1 ) + 1 * P ( 0 ) + 1 * E ( 1 ) + 1 * P ( 0 ) + 1 * E ( 1 ) + 1 * E ( 1 ) + 1 * P ( 0 ) + 1 * P ( 0 ) .$$

In the above examples, the semiconductor device 600 as shown in FIG. 26 can simplify the circuit structure and the control logic of the semiconductor device 600 by the inverse selection operation of the XOR logic circuit 6028, thereby reducing the power consumption of the circuit, and achieving the flexible selection of the multiple memory banks.

The compute-in-memory device as shown in FIG. 23, FIG. 24, or FIG. 25 may distribute the extra memory blocks into each memory bank, so that the relative physical address spans between the memory blocks in the same memory bank are relatively small and relatively fixed, the variation of the current distribution and the resistance effect may be reduced, and correspondingly, the threshold voltage (Vt) distribution is more converged, thereby improving the read and write performance, stability and reliability of the memory block.

However, when the memory cell 606 in the semiconductor device 600 is not accessed for a long time, as shown in FIG. 10, the charges on the trap layer 320 may gradually decrease due to leakage. Due to the influence of charge leakage and other physical factors, the data retention capability of the semiconductor device 600 may gradually decrease, resulting in a change in the threshold voltage of the memory cell 606, thereby affecting the accuracy, stability and reliability of the data.

In order to maintain the stability and reliability of the data, it is necessary to periodically update or refresh the data in the memory cell to re-inject charges and restore its original threshold voltage.

Due to the erase-before-write characteristics of the semiconductor device 1022, such as the NAND semiconductor device, for the data writing of the same logic address, modifications cannot be made on the basis of the physical address of the original stored data, and only a new physical address may be found to write the updated data.

For the data that has been updated, the data in the original physical address becomes invalid data. If the invalid data is not dealt with, the storage space of the NAND semiconductor device will be quickly exhausted. In this regard, the FTL 10242 releases the storage space by performing garbage collection.

Therefore, when the data in the memory bank is updated, the to-be-updated data needs to be migrated or moved first to a new physical address, and then the garbage collection is performed to erase data in the original physical address.

However, for the compute-in-memory device shown in FIG. 23, FIG. 24, or FIG. 25, the compute operation in the compute-in-memory operation is performed at a memory-bank level. When the garbage collection operation is performed, data erase is performed on a memory-block level. Since the level of the compute operation in performing a compute-in-memory operation does not match the level of performing the garbage collection operation, the wear of the memory blocks in the memory bank may be unbalanced.

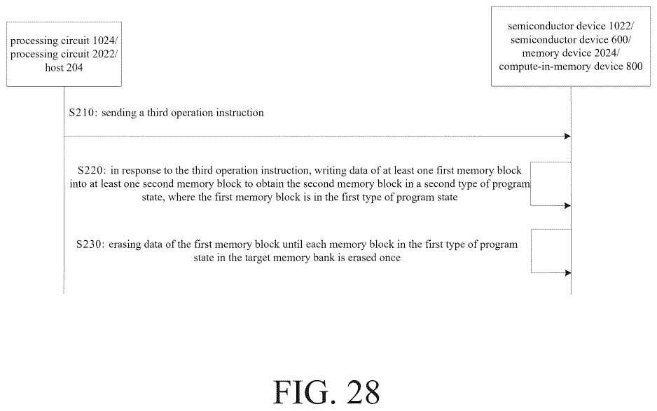

In order to solve the problem that the wear of the memory blocks in the memory bank may be unbalanced in the compute-in-memory device as shown in FIG. 23, FIG. 24, or FIG. 25 because the level of the compute operation in performing compute-in-memory operation does not match the level of performing the garbage collection operation, the present disclosure provides an operating method, which avoids wear imbalance of different memory blocks during garbage collection by performing rotational migration on data stored in a plurality of memory blocks in a memory bank. As shown in FIG. 28, the operating method comprises operations S210-S230:

S210: sending a third operation instruction.

S220: in response to the third operation instruction, writing data of at least one first memory block into at least one second memory block to obtain the second memory block in a second type of program state, where the first memory block is in the first type of program state.

S230: erasing data of the first memory block until each memory block in the first type of program state in the target memory bank is erased once.

In some optional implementations, the third operation instruction may be sent by the processing circuit 1024 shown in FIG. 1, FIG. 5, or FIG. 6, or the host 304 shown in FIG. 4, or the processing circuit 2022 in the semiconductor device 202 shown in FIG. 2 and FIG. 3.

The third operation instruction may be sent to the semiconductor device 1022 shown in FIG. 1, FIG. 4, FIG. 5, FIG. 6, or the semiconductor device 600 shown in FIG. 7, FIG. 8, FIG. 9, FIG. 11, FIG. 12, FIG. 16, FIG. 17, FIG. 21, FIG. 26, or the memory device 2024 in the semiconductor device 202 shown in FIG. 2 and FIG. 3, or the compute-in-memory device 800 shown in FIG. 23.

Taking the semiconductor device 600 as an example, as shown in FIG. 16, the semiconductor device 600 comprises a plurality of memory planes. Each of the memory planes comprises a plurality of memory banks, and each of the memory banks comprises a plurality of memory blocks. Each memory block comprises a first number of first type of memory blocks and a second number of second type of memory blocks. The first type of memory block is in a program state, and the second type of memory block is in an erase state, or is in an erase state after an erase operation is performed.

In some examples, the first type of memory block is in a program state. The memory block in the program state comprises a memory block in a first type of program state or a memory block in a second type of program state.

For example, a memory block in the first type of program state comprises a memory block in a program state in the target memory bank between two adjacent data migration cycles. A memory block in the second type of program state comprises a memory block on which a program operation is performed within one data migration cycle. One data migration cycle comprises a duration in which all the memory blocks in the first type of program state in the target memory bank are erased once. The target memory bank comprises any one of a plurality of memory banks.

The third operation instruction comprises third address information and fourth address information. The third address information is mapped to at least one first memory block, and the fourth address information is mapped to at least one second memory block. The first memory block comprises a memory block in a first type of program state, and the first memory block and the second memory block are different memory blocks in a plurality of memory blocks of the target memory bank.

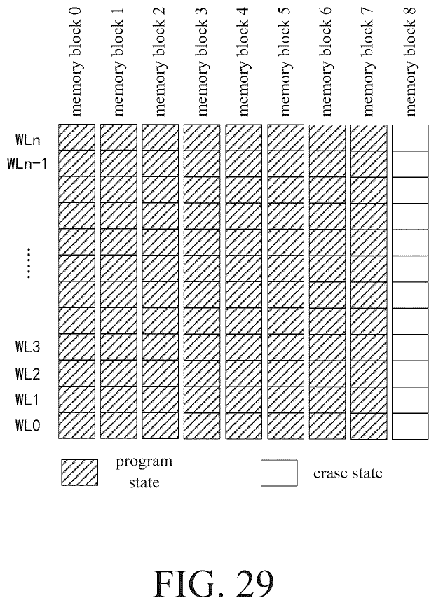

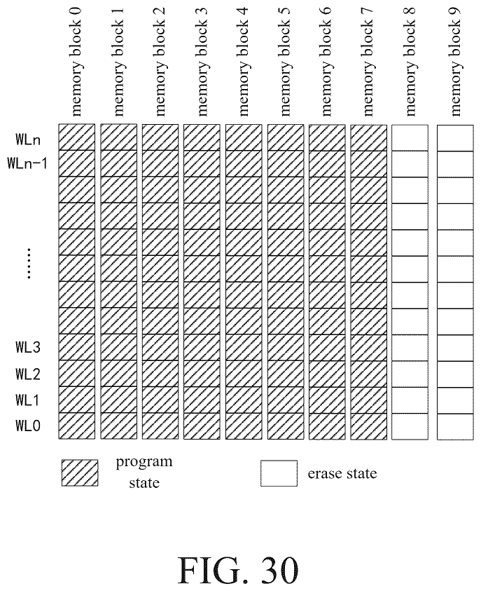

In some possible implementations, the first number is greater than the second number. The second number may be one (as shown in FIG. 29) or more (as shown in FIG. 30, taking the second number being two as an example).

In some examples, in a memory bank on which data migration operations need to be performed, a first number of memory blocks in a program state is greater than a second number of memory blocks in an erase state. As shown in FIG. 29, a first number of first type of memory blocks in a memory bank comprise a memory block 0 (block0), a memory block 1 (block1), a memory block 2 (block2), a memory block 3 (block3), a memory block 4 (block4), a memory block 5 (block5), a memory block 6 (block 6), and a memory block 7 (block 7), and the second number of second type of memory blocks comprise a memory block 8 (block8). The memory block 0, the memory block 1, the memory block 2, the memory block 3, the memory block 4, the memory block 5, the memory block 6, and the memory block 7 are in the first type of program state, and the memory block 8 is in an erase state.

In some other examples, FIG. 30 shows a memory bank. As shown in FIG. 30, a first number of first type of memory blocks in a memory bank comprise a memory block 0 (block0), a memory block 1 (block1), a memory block 2 (block2), a memory block 3 (block3), a memory block 4 (block4), a memory block 5 (block5), a memory block 6 (block 6) and a memory block 7 (block 7), and the second number of second type of memory blocks comprise a memory block 8 (block8) and a memory block 9 (block9). The memory block 0, the memory block 1, the memory block 2, the memory block 3, the memory block 4, the memory block 5, the memory block 6, and the memory block 7 are in the first type of program state, and the memory block 8 and the memory block 9 are in an erase state.

In an example, taking the memory bank shown in FIG. 29 as an example, a rotational migration is performed on the data stored in the memory blocks in the memory bank shown in FIG. 29. The third address information may be mapped to any one of the memory block 0, the memory block 1, the memory block 2, the memory block 3, the memory block 4, the memory block 5, the memory block 6, and the memory block 7, and the fourth address information may be mapped to the memory block 8. When the data in the memory block 0, the memory block 1, the memory block 2, the memory block 3, the memory block 4, the memory block 5, the memory block 6, and the memory block 7 are updated, to achieve wear leveling between different memory blocks, data in the memory block 0, the memory block 1, the memory block 2, the memory block 3, the memory block 4, the memory block 5, the memory block 6, and the memory block 7 may be respectively migrated once.

In some optional implementations, a relationship between a number of at least one first memory block and a number of at least one second memory block comprises at least two relationships: one is that the number of the at least one first memory block is greater than the number of the at least one second memory block; and the other one is that the number of the at least one first memory block is equal to the number of the at least one second memory block.

In some examples, the number of the at least one first memory block is greater than the number of the at least one second memory block, for example, a number of memory blocks mapped by the third address information is greater than a number of memory blocks mapped by the fourth address information. For example, in one data migration cycle, the memory bank may perform a garbage collection operation, and when performing the garbage collection operation, a storage space in the memory block occupied by valid data in the memory block is less than a storage space owned by the memory block. In this scenario, the valid data in a plurality of memory blocks may be migrated to a memory block in an erase state (or a memory block having an idle storage space).

In some other examples, the number of the at least one first memory block is equal to the number of the at least one second memory block, for example, a number of memory blocks mapped by the third address information is equal to a number of memory blocks mapped by the fourth address information. For example, the storage space in the memory block occupied by the valid data in the memory block is equal to the storage space of the memory block.

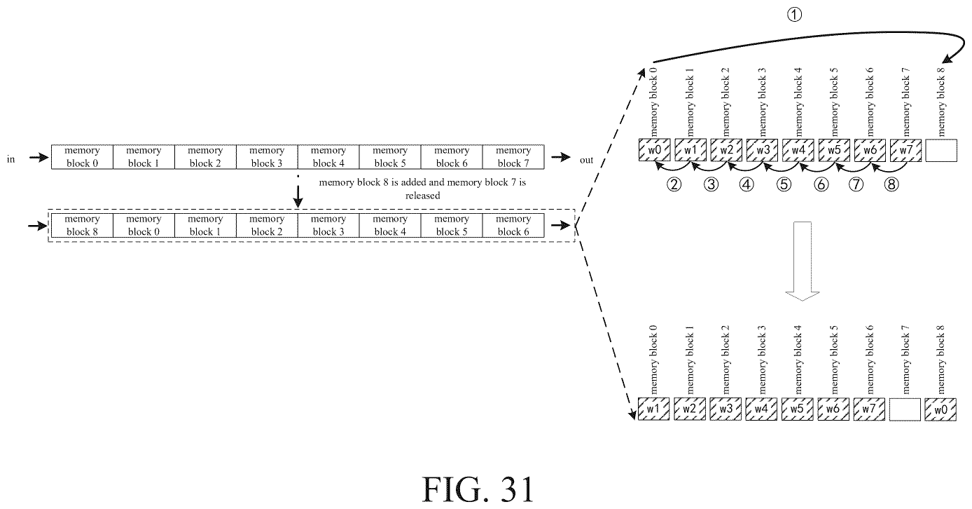

In some examples, taking an example that in a first data migration cycle, the memory block 8 is added and the memory block 7 is released to perform data rotational migration, as shown in FIG. 31:
Operation \textcircled{1}: migrating the data in the memory block 0 into the memory block 8, and then erasing the data in the memory block 0.
Operation \textcircled{2}: migrating the data in the memory block 1 into the memory block 0, and then erasing the data in the memory block 1.
Operation \textcircled{3}: migrating the data in the memory block 2 into the memory block 1, and then erasing the data in the memory block 2.
Operation \textcircled{4}: migrating the data in the memory block 3 into the memory block 2, and then erasing the data in the memory block 3.
Operation \textcircled{5}: migrating the data in the memory block 4 into the memory block 3, and then erasing the data in the memory block 4.
Operation \textcircled{6}: migrating the data in the memory block 5 into the memory block 4, and then erasing the data in the memory block 5.
Operation \textcircled{7}: migrating the data in the memory block 6 into the memory block 5, and then erasing the data in the memory block 6.
Operation \textcircled{8}: migrating the data in the memory block 7 into the memory block 6, and then erasing the data in the memory block 7.

After the first data migration cycle ends, the memory block 0, the memory block 1, the memory block 2, the memory block 3, the memory block 4, the memory block 5, the memory block 6, and the memory block 8 are in a program state, and the memory block 7 is in an erase state, for example, the space of the memory block 7 is released.

In some possible examples, for the memory bank as shown in FIG. 31, after the first data migration cycle is performed, when a second data migration cycle is performed, the memory block 0, the memory block 1, the memory block 2, the memory block 3, the memory block 4, the memory block 5, the memory block 6, and the memory block 8 are in the first type of program state, and the memory block 7 is in an erase state.

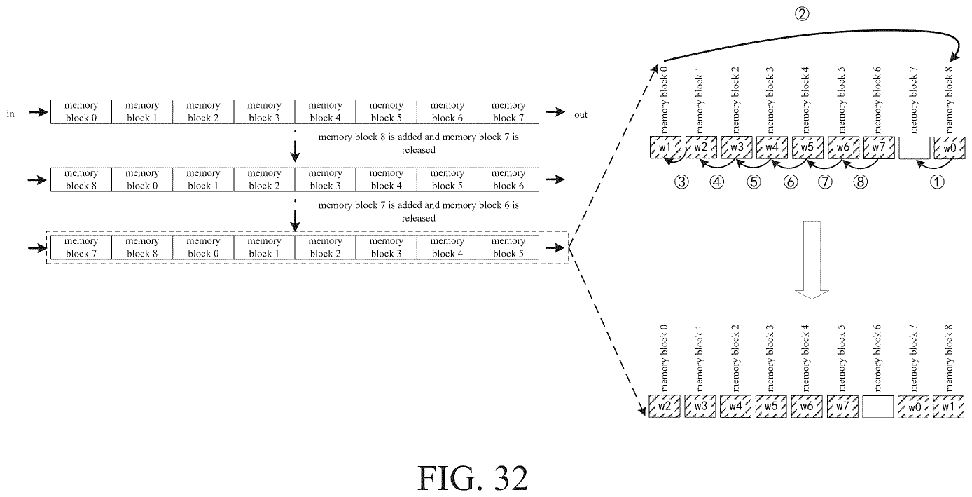

In the second data migration cycle, a first in first out (FIFO) policy may be followed. For example, between different data migration cycles, the order of data writing by the memory block is positively correlated with the order of data erasing by memory block. For example, data is first written (or migrated) into the memory block 8 in the first data migration cycle, data in the memory block 8 is first updated (or migrated out) in the next adjacent second data migration cycle, as shown in FIG. 32:
Operation \textcircled{1}: migrating the data in the memory block 8 into the memory block 7, and then erasing the data in the memory block 8.
Operation \textcircled{2}: migrating the data in the memory block 0 into the memory block 8, and then erasing the data in the memory block 0.
Operation \textcircled{3}: migrating the data in the memory block 1 into the memory block 0, and then erasing the data in the memory block 1.
Operation \textcircled{4}: migrating the data in the memory block 2 into the memory block 1, and then erasing the data in the memory block 2.
Operation \textcircled{5}: migrating the data in the memory block 3 into the memory block 2, and then erasing the data in the memory block 3.
Operation \textcircled{6}: migrating the data in the memory block 4 into the memory block 3, and then erasing the data in the memory block 4.
Operation \textcircled{7}: migrating the data in the memory block 5 into the memory block 4, and then erasing the data in the memory block 5.
Operation \textcircled{8}: migrating the data in the memory block 6 into the memory block 5, and then erasing the data in the memory block 6.

After the second data migration cycle ends, the space of the memory block 6 is released.

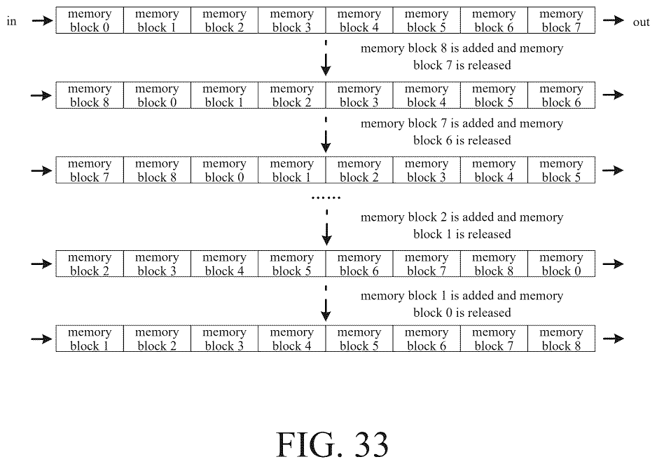

In some possible implementations, in a plurality of data migration cycles. data migration is performed on data stored in memory blocks in a memory bank, and a result is shown in FIG. 33.

As shown in FIG. 31, FIG. 32, and FIG. 33, a rotational migration is performed on the data stored in the memory blocks in the memory bank, which means that the chance that each memory block is selected for read and write operation is equal, thereby facilitating to maintain the stability and reliability of the system, ensuring that all the memory blocks can be processed equally, so as to achieve wear leveling of the memory blocks in the memory bank.

It should be noted that, the processes of performing rotational migrations on data stored in memory blocks of a memory bank as shown in FIG. 31, FIG. 32, and FIG. 33 follows a first in first out (FIFO) policy between different rotation cycles.

The implementation of the FIFO policy is relatively simple and does not require complex algorithms or data structures to support. This simplification helps to reduce management costs and improve management efficiency. Meanwhile, under the FIFO policy, the rotation order of the memory blocks is predictable. This helps the system better plan and allocate resources. For example, the system may prepare the data in advance according to the rotation order of the memory blocks, thereby improving the speed of data access. In addition, the FIFO policy may also avoid resource idleness and waste, and ensure that resources in the memory bank are fully utilized.

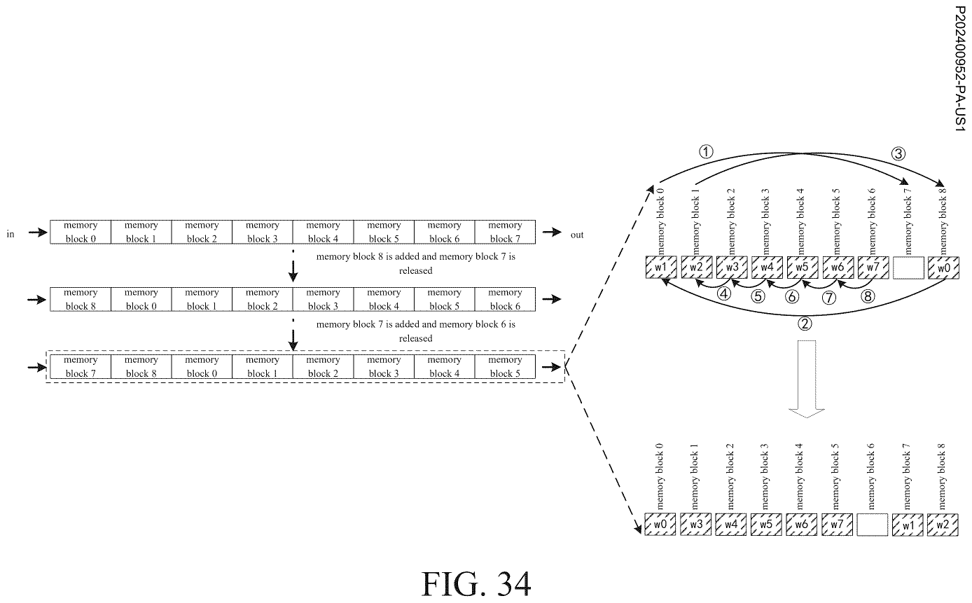

The rotational migration of the data stored in the memory blocks in the memory bank by the FIFO policy is an example solution, but the effect of implementing wear leveling is not limited to the FIFO policy, and it is only required to rotate all the memory blocks in the memory bank in one rotation cycle, for example, as shown in FIG. 34:
Operation \textcircled{1}: migrating the data in the memory block 0 into the memory block 7, and then erasing the data in the memory block 0.
Operation \textcircled{2}: migrating the data in the memory block 8 into the memory block 0, and then erasing the data in the memory block 8.
Operation \textcircled{3}: migrating the data in the memory block 1 into the memory block 8, and then erasing the data in the memory block 1.
Operation \textcircled{4}: migrating the data in the memory block 2 into the memory block 1, and then erasing the data in the memory block 2.
Operation \textcircled{5}: migrating the data in the memory block 3 into the memory block 2, and then erasing the data in the memory block 3.
Operation \textcircled{6}: migrating the data in the memory block 4 into the memory block 3, and then erasing the data in the memory block 4.
Operation \textcircled{7}: migrating the data in the memory block 5 into the memory block 4, and then erasing the data in the memory block 5.
Operation \textcircled{8}: migrating the data in the memory block 6 into the memory block 5, and then erasing the data in the memory block 6.

In some possible implementations, in the process of performing rotational migration on the data in the memory block in the memory bank, since the data memory position changes, the mapping relationship between the input data (or the input vector) and the weight data memory position may be changed.

In some examples, when performing the compute-in-memory operation as shown in FIG. 25, at least one address information of the following address spaces may be involved: Plane_add, Bank_add, WL_Add, Head_Add, Unsel_blk.
Plane_add: represents address of a memory plane.
Bank_add: represents address of a memory bank.
WL_Add: represents selected WL during compute-in-memory operation.
Head_Add: represents address of a start memory block in memory blocks in a program state (memory blocks configured to input an “input data/input vector” or store “weight data/weight vector”).
Unsel_blk: represents address of a memory block in an erase state (a memory block not selected by “input data/input vector” or a memory block on which “weight data/weight vector” is not stored).

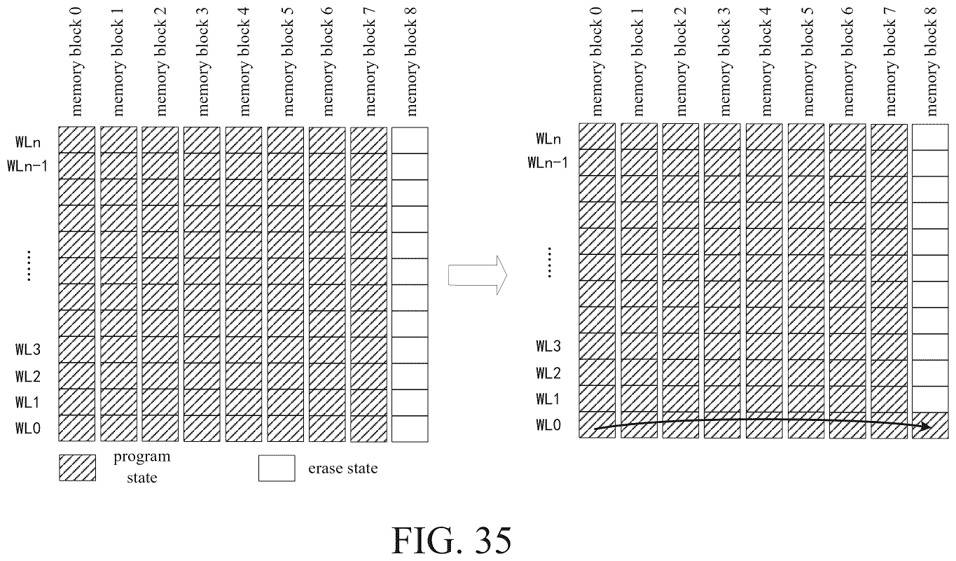

In an example, as shown in FIG. 35, after data migration of WL0 in the memory block 0 is completed, input data corresponding to the WL0 in the original memory block 0 needs to be mapped to WL0 in the memory block 8, and the input data originally mapped to the WL0 in the memory block 0 needs to be adjusted to be mapped to the data of the WL0 in the memory block 8.

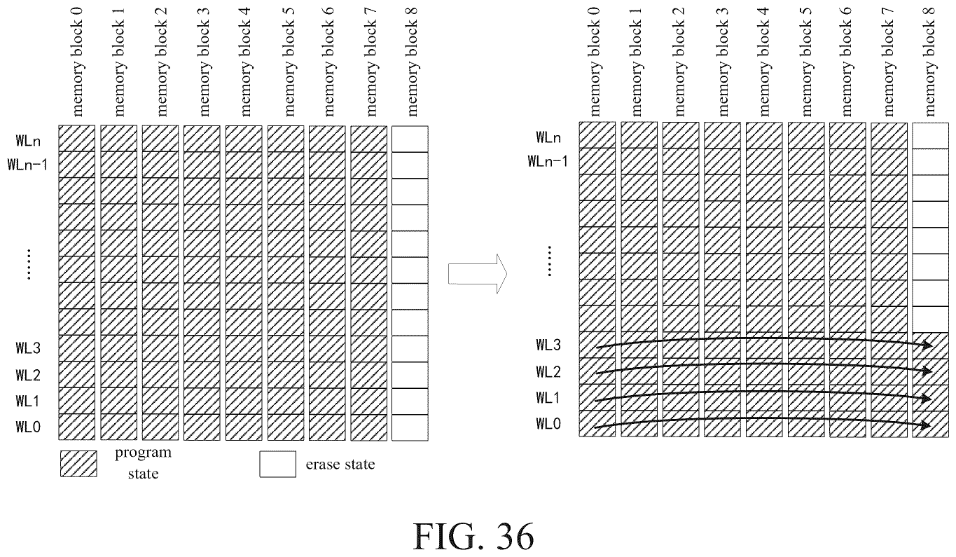

In another example, as shown in FIG. 36, after data migration of WL0~WL3 in the memory block 0 is completed, input data corresponding to WL0~WL3 in the original memory block 0 needs to be mapped to WL0~WL3 in memory block 8, and the input data originally mapped to the data of WL0~WL3 in the memory block 0 needs to be adjusted to be mapped to the data of WL0~WL3 in the memory block 8.

In yet another example, when a rotational migration is performed on data, the manner in which the mapping relationship is adjusted is not limited to the manner shown in FIG. 35 or FIG. 36, for example, the mapping relationship may also be adjusted after all data in the memory block 0 is migrated to the memory block 8.

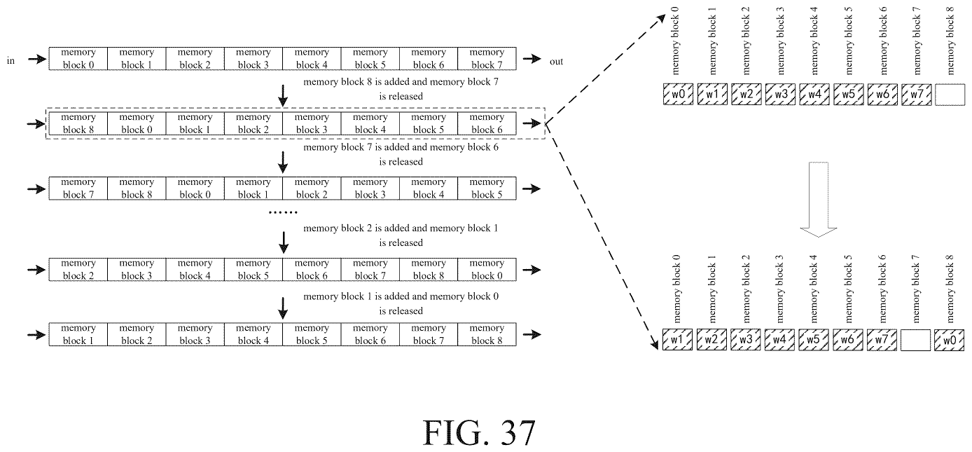

For example, as shown in FIG. 37, neither address of the memory plane nor address of the memory bank changes, and WL does not change for each weight data, while Head Add and Unsel_Add change, for example, Head_Add changes from memory block 0 to memory block 8, and Unsel_blk changes from memory block 8 to memory block 7.

As shown in operations S210-S230 shown in FIG. 28, the data migration operation is completed in the same memory bank, but in some scenarios, it may also be necessary to migrate data in one memory bank to another memory bank, for example:

In a first scenario, a number of failed memory blocks in one memory bank is greater than a threshold. The memory bank is marked as a failed memory bank and is not configured to perform a corresponding operation. Data migration between memory banks is triggered in the scenario.

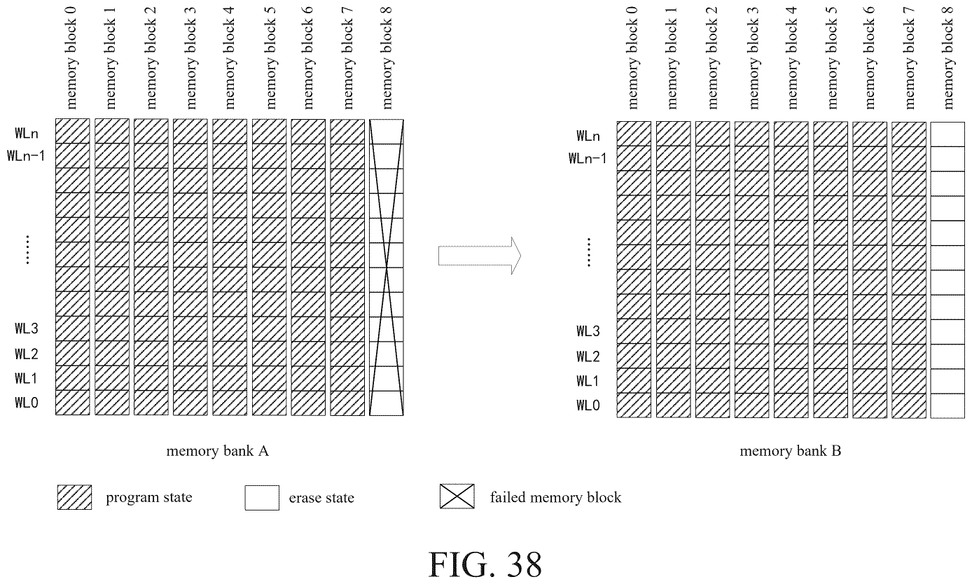

In some examples, taking the memory bank shown in FIG. 29 as an example, as shown in FIG. 38, when the memory block 8 in the memory bank A is a failed memory block, because all the extra memory blocks in the memory bank become failed memory blocks, data migration between the memory banks is triggered, and data in the memory bank A is migrated to the memory bank B.

In a second scenario, when the erase counts of different memory banks are different and the difference between the erase counts is greater than a threshold, in order to achieve wear leveling among different memory banks, data in a memory bank with a larger erase count may be migrated to a memory bank with a smaller erase count.

In some examples, such as when |ec_max-ec_min|>=ec_wl_limit (leveling threshold) is satisfied between the memory banks, data migration between the memory banks is triggered. The erase count (EC) of the memory bank takes the EC mean value of all the memory blocks in the memory bank, or takes the EC corresponding to the memory block in an erase state (Free-block) as the memory bank EC. The ec_max represents an erase count of the memory bank with the maximum erase count, and ec_min represents an erase count of the memory bank with the minimum erase count.

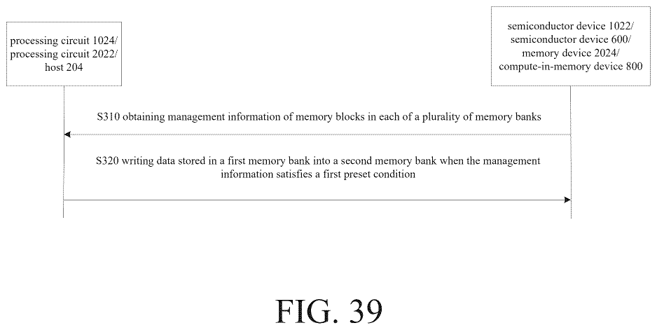

In some possible implementations, when the first scenario is satisfied, the performance of data migration between different memory banks is triggered, as shown in FIG. 39, comprising operation S310-operation S320:

S310: obtaining management information of memory blocks in each of a plurality of memory banks.

In some examples, a memory block in the memory bank comprises a plurality of pages, and one page comprised in the plurality of pages stores the management information. The management information is configured to indicate whether the memory block is a failed memory block.

In some examples, when the management information is 0xFF, it indicates that the current memory block is a failed memory block.

S320: writing data stored in a first memory bank into a second memory bank when the management information satisfies a first preset condition.

In some examples, the first memory bank and the second memory bank are both any one of the plurality of memory banks and the first memory bank and the second memory bank are different. The first preset condition may be that a number of failed memory blocks in the first memory bank is greater than or equal to a first threshold and a number of failed memory blocks in the second memory bank is less than a second threshold.

In some examples, taking an example in which each memory bank comprises a first number of first type of memory blocks and a second number of second type of memory blocks, the first number of the first type of memory blocks are in a program state, and the second number of the second type of memory blocks are configured to replace the failed memory blocks in the first number of the first type of memory blocks. The first threshold is greater than or equal to the second number, and the second threshold is less than the second number, for example, the condition in the first scenario is satisfied. The magnitudes of the first threshold and the second threshold may be the same or different, and the magnitudes of the first threshold and the second threshold may be determined according to actual needs, which is not limited herein.

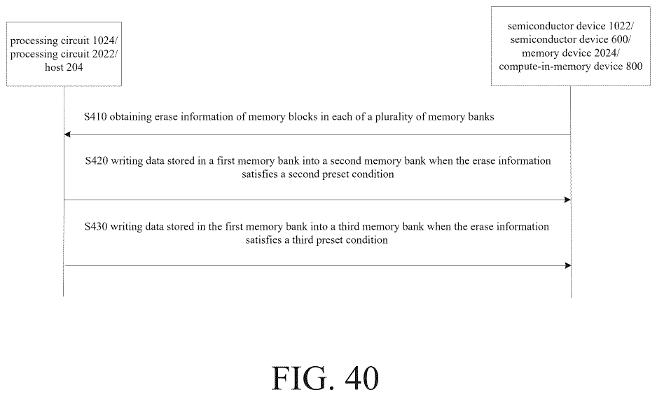

In some possible implementations, when the second scenario is satisfied, the performance of data migration between different memory banks is triggered, as shown in FIG. 40, comprising operation S410-operation S430:

S410: obtaining erase information of memory blocks in each of a plurality of memory banks.

In some examples, the erase information may comprise an erase count of the memory bank, where the erase count of the memory bank comprises a mean value of the erase counts of the memory blocks in the memory bank, or the erase count of the memory bank comprises a mean value of the erase counts of the memory blocks in the erase state in the memory bank.

S420: writing data stored in a first memory bank into a second memory bank when the erase information satisfies a second preset condition.

In some examples, both the first memory bank and the second memory bank are any one of the plurality of memory banks, and the first memory bank is different from the second memory bank. The second preset condition may be that an erase count of the first memory bank is greater than a third threshold and an erase count of the second memory bank is less than a fourth threshold. The magnitudes of the third threshold and the fourth threshold may be the same or different, and the magnitudes of the third threshold and the fourth threshold may be determined according to actual needs, which is not limited herein.

S430: writing data stored in the first memory bank into a third memory bank when the erase information satisfies a third preset condition.

In some examples, the third preset condition may be that a difference between the erase count of the first memory bank and the erase count of the second memory bank is greater than a fifth threshold. The maximum erase count of the first memory bank is ec_max, and the minimum erase count of the second memory bank is ec_min. The third memory bank comprises any of the plurality of memory banks and is different from the first memory bank. The magnitude of the fifth threshold may be determined according to actual needs, which is not limited herein.

For the compute-in-memory device shown in FIG. 23, FIG. 24, or FIG. 25, after performing data rotational migration in the memory bank or performing data migration between memory banks, the memory bank is configured to perform a corresponding operation, and the corresponding operation comprises at least one of: a data write operation, a data read operation, a data erase operation, or a compute-in-memory operation.

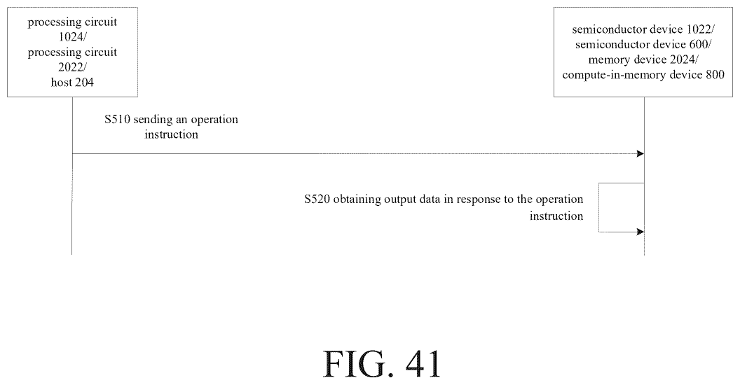

Taking the memory bank being configured to perform the compute-in-memory operation as an example, as shown in FIG. 41, this example provides a compute-in-memory operating method, comprising operation S510-operation S520:

S510: sending an operation instruction.

In some possible implementations, the operation instruction may be sent by the processing circuit 1024 shown in FIG. 1, FIG. 5, or FIG. 6, or the host 304 shown in FIG. 4, or the processing circuit 2022 in the semiconductor device 202 shown in FIG. 2 and FIG. 3.

The operation instruction may be sent to the semiconductor device 1022 shown in FIG. 1, FIG. 4, FIG. 5, FIG. 6, or the semiconductor device 600 shown in FIG. 7, FIG. 8, FIG. 9, FIG. 11, FIG. 12, FIG. 16, FIG. 17, FIG. 21, FIG. 26, or the memory device 2024 in the semiconductor device 202 shown in FIG. 2 and FIG. 3, or the compute-in-memory device 800 shown in FIG. 23.

In some examples, the operation instruction may be a first operation instruction or a second operation instruction.

In an example, the first operation instruction comprises first address information and input data. The first address information is mapped to a second type of memory block in the target memory bank. For example, the first address information may be Unsel_blk, representing an address of a memory block in an erase state (a memory block not selected by “input data/input vector” or a memory block on which “weight data/weight vector” is not stored).

In an example, the second operation instruction comprises the first address information, second address information, and input data. The second address information is mapped to a start memory block in the first type of memory blocks in the target memory bank. For example, the second address information may be Head_Add, representing an address of a start memory block in memory blocks in a program state (memory blocks configured to input an “input data/input vector” or store “weight data/weight vector”).

In another example, a memory block in the target memory bank comprises select lines, word lines, and memory strings. The memory string comprises a plurality of transistors. Drain lines and source lines of the transistors are alternately coupled. A gate of the transistor is coupled to the word line, and a select line is coupled to a gate line of the transistor at one end of the memory string. The first operation instruction or the second operation instruction further comprises address information of the selected word line in the target memory block, for example, comprising WL_Add representing the selected word line WL during the compute-in-memory operation.

S520: obtaining output data in response to the operation instruction.

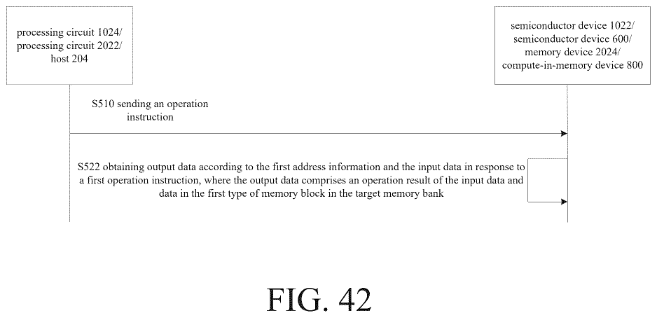

In some examples, when the operation instruction comprises the first operation instruction, and the first operation instruction comprises the first address information and the input data, as shown in FIG. 42, the operation S520 comprises operation S522:

S522: obtaining output data according to the first address information and the input data in response to a first operation instruction, where the output data comprises an operation result of the input data and data in the first type of memory block in the target memory bank. The operation principle may be, but is not limited to, the implementation shown in FIG. 25.

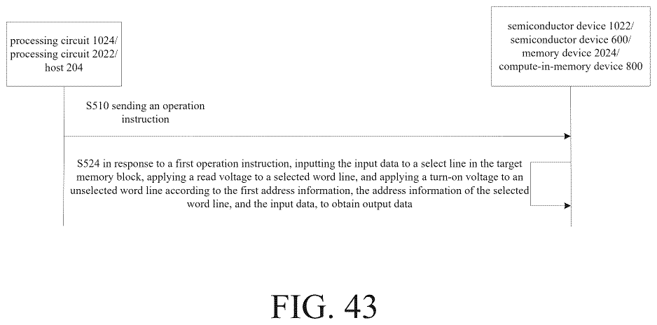

In some examples, when the operation instruction comprises the first operation instruction, and the first operation instruction comprises the first address information, the input data, and the address information of the selected word line, as shown in FIG. 43, the operation S520 comprises the operation S524:

S524: in response to a first operation instruction, inputting the input data to a select line in the target memory block, applying a read voltage to a selected word line, and applying a turn-on voltage to an unselected word line according to the first address information, the address information of the selected word line, and the input data, to obtain output data.

The output data comprises a current output from the drain line or the source line, and the turn-on voltage is greater than the read voltage. The operation principle may be, but is not limited to, the implementation shown in FIG. 25.

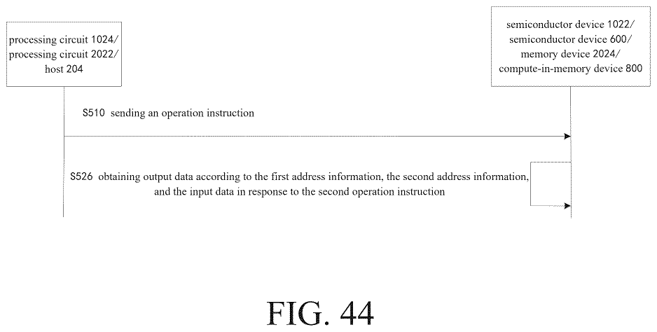

In some examples, when the operation instruction comprises the second operation instruction, and the second operation instruction comprises the first address information, the second address information, and the input data, as shown in FIG. 44, the operation S520 comprises operation S526:

S526: obtaining output data according to the first address information, the second address information, and the input data in response to the second operation instruction.

The output data comprises an operation result of the input data and data in the first type of memory block in the target memory bank. The operation principle may be, but is not limited to, the implementation shown in FIG. 25.

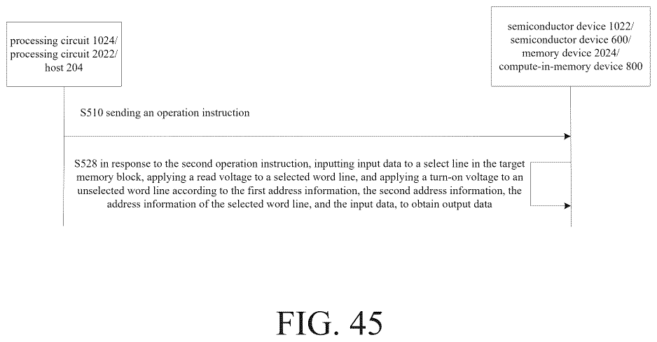

In some examples, when the operation instruction comprises the second operation instruction, and the second operation instruction comprises the first address information, the second address information, the input data, and the address information of the selected word line, as shown in FIG. 45, the operation S520 comprises operation S528:

S528: in response to the second operation instruction, inputting input data to a select line in the target memory block, applying a read voltage to a selected word line, and applying a turn-on voltage to an unselected word line according to the first address information, the second address information, the address information of the selected word line, and the input data, to obtain output data.

The output data comprises a current output from the drain line or the source line, and the turn-on voltage is greater than the read voltage. The operation principle may be, but is not limited to, the implementation shown in FIG. 25.

An example of this application further provides a computer-readable storage medium comprising instructions. The instructions, when operating on the electronic device or the memory system recited in the above examples, cause the electronic device or the memory system performs the operating methods recited in the above examples.

The above descriptions are only specific implementations of the present disclosure, but the protection scope of the present disclosure is not limited thereto, and changes or replacements that may be easily conceived by any person skilled in the art within the technical scope of the present disclosure should be covered within the protection scope of the present disclosure. Therefore, the protection scope of the present disclosure should be defined by the protection scope of the claims.

What is claimed is:

1. A semiconductor device, comprising:
a memory cell array comprising memory planes, wherein each of the memory planes comprises memory banks, and each of the memory banks comprises at least one memory block in a first type of program state; and
a peripheral circuit coupled to the memory cell array and configured to:
write data of at least one first memory block into at least one second memory block to obtain the second memory block in a second type of program state, wherein the first memory block and the second memory block are different memory blocks in memory blocks of a target memory bank, and the first memory block comprises a memory block in the first type of program state; and
erase data of the first memory block until each memory block in the first type of program state in the target memory bank is erased once.

2. The semiconductor device of claim 1, wherein a memory block in the first type of program state comprises a memory block in a program state in the target memory bank between two adjacent data migration cycles, a memory block in the second type of program state comprises a memory block on which a program operation is performed within one data migration cycle, and one data migration cycle comprises a duration in which each memory block in the first type of program state in the target memory bank is erased once.

3. The semiconductor device of claim 1, wherein:
a number of the at least one first memory block is greater than a number of the at least one second memory block, or
the number of the at least one first memory block is equal to the number of the at least one second memory block.

4. The semiconductor device of claim 1, wherein:
each of the memory banks comprises a first type of memory block and a second type of memory block,
the first type of memory block is in a program state and a number of at least one memory block in the program state in the target memory bank is equal to a first number,
a memory block in the program state comprises a memory block in the first type of program state or a memory block in the second type of program state,
the second type of memory block is in an erase state or is in an erase state after an erase operation is performed,
a number of at least one memory block in the erase state in the target memory bank is equal to a second number, and
the second type of memory block is further configured to replace a failed memory block in at least one first type of memory block.

5. The semiconductor device of claim 1, wherein the peripheral circuit is further configured to:
write data stored in a first memory bank into a second memory bank, wherein the first memory bank comprises any one of the memory banks, a number of at least one failed memory block in the first memory bank is greater than or equal to a first threshold, and the second memory bank comprises any one of the memory banks and a number of at least one failed memory block in the second memory bank is less than a second threshold,
wherein each of the memory banks comprises a first type of memory block and a second type of memory block, a number of at least one first type of memory block is equal to a first number, and a number of at least one second type of memory block is equal to a second number;
wherein the first type of memory blocks is in a program state and the second type of memory block is configured to replace a failed memory block in at least one first type of memory block, and
wherein the first threshold is greater than or equal to the second number and the second threshold is less than the second number.

6. The semiconductor device of claim 1, wherein the peripheral circuit is further configured to write data stored in a first memory bank into a second memory bank, the first memory bank comprises any one of the memory banks and an erase count of the first memory bank is greater than a third threshold, the second memory bank comprises any one of the memory banks and an erase count of the second memory bank is less than a fourth threshold, and an erase count of a memory bank comprises a mean value of erase counts of the memory blocks in the memory bank or the erase count of the memory bank comprises a mean value of at least one erase count of at least one memory block in an erase state in the memory bank.

7. The semiconductor device of claim 6, wherein the peripheral circuit is further configured to write data stored in a first memory bank into a third memory bank when a difference between an erase count of the first memory bank and an erase count of the second memory bank is greater than a fifth threshold, an erase count of a memory bank comprises a mean value of erase counts of the memory blocks in the memory bank or the erase count of the memory bank comprises a mean value of at least one erase count of at least one memory block in an erase state in the memory bank, the first memory bank comprises any one of the memory banks and the erase count of the first memory bank is maximum, the second memory bank comprises any one of the memory banks and the erase count of the second memory bank is minimum, and the third memory bank comprises any one of the memory banks and is different from the first memory bank.

8. The semiconductor device of claim 1, wherein between different data migration cycles, an order in which data is written to memory blocks and an order in which data erase is performed on memory blocks are positively correlated, and one data migration cycle comprises a duration in which each memory block in the first type of program state in the target memory bank is erased once.

9. The semiconductor device of claim 1, wherein each of the memory banks comprises a first type of memory block and a second type of memory block, the first type of memory block is configured to perform a corresponding operation, and the second type of memory block is configured to replace a failed memory block in at least one first type of memory block;
wherein the peripheral circuit is further configured to control the first type of memory block in the target memory bank to perform a corresponding operation according to first address information, and the first address information is mapped to the second type of memory block in the target memory bank; and
wherein the corresponding operation comprises at least one of a data write operation, a data read operation, a data erase operation, or a compute-in-memory operation.

10. The semiconductor device of claim 9, wherein the first type of memory block is configured to perform a compute-in-memory operation, and the peripheral circuit is configured to:
receive a first operation instruction, wherein the first operation instruction comprises the first address information and input data, and the first address information is mapped to the second type of memory block in the target memory bank; and
obtain output data according to the first address information and the input data in response to the first operation instruction, wherein the output data comprises an operation result of the input data and data in the first type of memory block in the target memory bank.

11. The semiconductor device of claim 10, wherein a memory block in the target memory bank comprises a select line, a word line, and a memory string, the memory string comprises transistors, a drain line and a source line of the transistor are alternately coupled, a gate of the transistor is coupled to the word line, and the select line is coupled to a gate line of the transistor at one end of the memory string, and the first operation instruction further comprises address information of a selected word line in the target memory block,
wherein the peripheral circuit is configured to, in response to the first operation instruction:
input the input data to the select line in the target memory block;
apply a read voltage to the selected word line; and
apply a turn-on voltage to an unselected word line according to the first address information, the address information of the selected word line, and the input data to obtain output data, wherein the output data comprises a current output from the drain line or the source line, and the turn-on voltage is greater than the read voltage.

12. The semiconductor device of claim 9, wherein the peripheral circuit is configured to control the first type of memory block in the target memory bank to perform a corresponding operation according to the first address information and second address information, and wherein the second address information is mapped to a start memory block in the first type of memory block in the target memory bank.

13. The semiconductor device of claim 12, wherein the first type of memory block is configured to perform a compute-in-memory operation, and the peripheral circuit is configured to:
receive a second operation instruction, wherein the second operation instruction comprises the first address information, the second address information, and input data; and
obtain output data according to the first address information, the second address information, and the input data in response to the second operation instruction, wherein the output data comprises an operation result of the input data and data in the first type of memory block in the target memory bank.

14. The semiconductor device of claim 13, wherein a memory block in the target memory bank comprises a select line, a word line, and a memory string, the memory string comprises transistors, a drain line and a source line of the transistor are alternately coupled, a gate of the transistor is coupled to the word line, and the select line is coupled to a gate line of the transistor at one end of the memory string, and the second operation instruction further comprises address information of a selected word line in the target memory block,
wherein the peripheral circuit is configured to, in response to the second operation instruction:
input the input data to the select line in the target memory block;
apply a read voltage to the selected word line; and
apply a turn-on voltage to an unselected word line according to the first address information, the second address information, the address information of the selected word line, and the input data to obtain output data, wherein the output data comprises a current output from the drain line or the source line, and the turn-on voltage is greater than the read voltage.

15. An operating method of a semiconductor device, comprising:
writing data of at least one first memory block into at least one second memory block to obtain the second memory block in a second type of program state, wherein the first memory block and the second memory block are different memory blocks in memory blocks of a target memory bank, and the first memory block comprises a memory block in a first type of program state; and
erasing data of the first memory block until each memory block in the first type of program state in the target memory bank is erased once.

16. The operating method of claim 15, further comprising:
writing data stored in a first memory bank into a second memory bank, wherein the first memory bank comprises any one of the memory blocks, a number of at least one failed memory block in the first memory bank is greater than or equal to a first threshold, the second memory bank comprises any one of the memory blocks, and a number of at least one failed memory block in the second memory bank is less than a second threshold.

17. The operating method of claim 15, further comprising:
writing data stored in a first memory bank into a second memory bank, wherein the first memory bank comprises any one of the memory blocks and an erase count of the first memory bank is greater than a third threshold, the second memory bank comprises any one of the memory blocks and an erase count of the second memory bank is less than a fourth threshold, and an erase count of a memory bank comprises a mean value of erase counts of the memory blocks in the memory bank, or the erase count of the memory bank comprises a mean value of at least one erase count of at least one memory block in an erase state in the memory bank.

18. The operating method of claim 15, further comprising:
writing data stored in a first memory bank into a third memory bank when a difference between an erase count of the first memory bank and an erase count of the second memory bank is greater than a fifth threshold,
wherein an erase count of a memory bank comprises a mean value of erase counts of the memory blocks in the memory bank, or the erase count of the memory bank comprises a mean value of at least one erase count of at least one memory block in an erase state in the memory bank, the first memory bank comprises any one of the memory blocks and the erase count of the first memory bank is maximum, the second memory bank comprises any one of the memory blocks and the erase count of the second memory bank is minimum, and the third memory bank comprises any one of the memory blocks and is different from the first memory bank.

19. The operating method of claim 15, further comprising:
controlling the first type of memory block in the target memory bank to perform a corresponding operation according to first address information, wherein the first address information is mapped to the second type of memory block in the target memory bank, and wherein controlling the first type of memory block in the target memory bank to perform the corresponding operation according to the first address information comprises:
receiving a first operation instruction, wherein the first operation instruction comprises the first address information and input data, and the first address information is mapped to the second type of memory block in the target memory bank; and
obtaining output data according to the first address information and the input data in response to the first operation instruction, wherein the output data comprises an operation result of the input data and data in the first type of memory block in the target memory bank.

20. A memory system, comprising:
a processing circuit; and
a semiconductor device coupled to the processing circuit, the semiconductor device comprising:
a memory cell array comprising memory planes, wherein each of the memory planes comprises memory banks, and each of the memory banks comprises at least one memory block in a first type of program state; and
a peripheral circuit coupled to the memory cell array and configured to:
write data of at least one first memory block into at least one second memory block to obtain the second memory block in a second type of program state, wherein the first memory block and the second memory block are different memory blocks in memory blocks of a target memory bank, and the first memory block comprises a memory block in the first type of program state; and
erase data of the first memory block, until each memory block in the first type of program state in the target memory bank is erased once.
